(19) United States
(12) Patent Application Publication
(10) Pub. No.: US 2025/0107342 A1
(43) Pub. Date: Mar. 27, 2025

(54) DISPLAY PANEL, DISPLAY APPARATUS, AND METHOD OF FABRICATING DISPLAY PANEL

(71) Applicants: Beijing BOE Technology Development Co., Ltd., Beijing (CN); BOE Technology Group Co., Ltd., Beijing (CN)

(72) Inventors: Hejin Wang, Beijing (CN); Dengyun Chen, Beijing (CN); Zheng Liu, Beijing (CN); Shiming Shi, Beijing (CN)

(73) Assignees: Beijing BOE Technology Development Co., Ltd., Beijing (CN); BOE Technology Group Co., Ltd., Beijing (CN)

(21) Appl. No.: 18/729,631

(22) PCT Filed: Sep. 22, 2023
(86) PCT No.: PCT/CN2023/120638

§ 371 Date: Jul. 17, 2024

(51) Int. Cl. H10K 59/122; H10K 59/12; H10K 59/80

(52) U.S. Cl. CPC H10K 59/122; H10K 59/1201; H10K 59/80522

(57) ABSTRACT

A display panel includes a base substrate; an anode material layer including an anode of a light emitting element on the base substrate; a pixel definition layer on a side of the anode material layer away from the base substrate, and defining a subpixel aperture; an organic material layer at least partially in the subpixel aperture and on a side of the anode away from the base substrate; a cathode layer on a side of the organic material layer away from the base substrate; and a first auxiliary cathode layer on a side of the pixel definition layer away from the base substrate. The first auxiliary cathode layer is connected to the cathode layer, and includes a conductive material. An orthographic projection of the first auxiliary cathode layer on the base substrate at least partially overlaps with an orthographic projection of the pixel definition layer on the base substrate.

### TECHNICAL FIELD

The present invention relates to display technology, more particularly, to a display panel, a display apparatus, and a method of fabricating a display panel.

### BACKGROUND

Flexible electronic apparatuses and stretchable electronic apparatuses have been developed in recent years. Flexible electronic apparatuses are apparatuses that may be bent or folded, typically fabricated by mounting an electronic device on a flexible base substrate. Stretchable electronic apparatuses are apparatuses that allows its length to be increased in one or more dimensions. Stretchable electronic apparatuses may be useful in various applications including in display apparatuses and sensor arrays.

### SUMMARY

In one aspect, the present disclosure provides a display panel, comprising a base substrate; an anode material layer comprising an anode of a light emitting element on the base substrate; a pixel definition layer on a side of the anode material layer away from the base substrate, and defining a subpixel aperture; an organic material layer at least partially in the subpixel aperture and on a side of the anode away from the base substrate; a cathode layer on a side of the organic material layer away from the base substrate; and a first auxiliary cathode layer on a side of the pixel definition layer away from the base substrate; wherein the first auxiliary cathode layer is connected to the cathode layer; the first auxiliary cathode layer comprises a conductive material; an orthographic projection of the first auxiliary cathode layer on the base substrate at least partially overlaps with an orthographic projection of the pixel definition layer on the base substrate.

Optionally, the anode material layer further comprises a second auxiliary cathode layer; wherein the first auxiliary cathode layer is connected to the second auxiliary cathode layer.

Optionally, the display panel further comprises a third auxiliary cathode layer on a side of the anode material layer close to the base substrate; wherein the second auxiliary cathode layer is connected to the third auxiliary cathode layer.

Optionally, the orthographic projection of the pixel definition layer on the base substrate substantially covers the orthographic projection of the first auxiliary cathode layer on the base substrate.

Optionally, the first auxiliary cathode layer is in direct contact with the pixel definition layer.

Optionally, the orthographic projection of the first auxiliary cathode layer on the base substrate has a ring shape; and the orthographic projection of the first auxiliary cathode layer on the base substrate substantially surrounds at least a portion of an orthographic projection of the organic material layer on the base substrate.

Optionally, the orthographic projection of the first auxiliary cathode layer on the base substrate has a ring shape comprising connected multiple rings having multiple openings; and a respective ring of the connected multiple rings substantially surrounds at least a portion of an orthographic projection of the organic material layer in a respective light emitting element of multiple light emitting elements on the base substrate.

Optionally, an orthographic projection of the cathode layer on the base substrate overlaps with the orthographic projection of the first auxiliary cathode layer on the base substrate, forming a first overlapping region; the first overlapping region has a ring shape; and the first overlapping region substantially surrounds at least a portion of an orthographic projection of the organic material layer on the base substrate.

Optionally, the cathode layer is in direct contact with the first auxiliary cathode layer in a region corresponding to the first overlapping region.

Optionally, an orthographic projection of the organic material layer on the base substrate overlaps with the orthographic projection of the first auxiliary cathode layer on the base substrate, forming a second overlapping region; the second overlapping region has a ring shape; and the second overlapping region substantially surrounds at least a portion of an orthographic projection of the cathode layer on the base substrate.

Optionally, the organic material layer is in direct contact with the first auxiliary cathode layer in a region corresponding to the second overlapping region.

Optionally, the first auxiliary cathode layer comprises a second sub-layer and a third sub-layer on a side of the second sub-layer away from the base substrate.

Optionally, the second sub-layer has a second width along a plane intersecting with the first auxiliary cathode layer and two adjacent light emitting elements in two adjacent subpixels, respectively, and perpendicular to the base substrate; the third sub-layer bas a third width along the plane intersecting with the first auxiliary cathode layer and two adjacent light emitting elements in two adjacent subpixels, respectively, and perpendicular to the base substrate; and the third width is greater than the second width.

Optionally, an orthographic projection of the third sub-layer on the base substrate substantially covers an orthographic projection of the second sub-layer on the base substrate.

Optionally, the display panel further comprises a residual organic material layer on a side of the first auxiliary cathode layer away from the base substrate; and wherein an orthographic projection of the residual organic material layer on the base substrate at least partially overlaps with the orthographic projection of the first auxiliary cathode layer on the base substrate.

Optionally, the display panel further comprises a residual cathode material layer on a side of the residual organic material layer away from the first auxiliary cathode layer; and wherein an orthographic projection of the residual cathode material layer on the base substrate at least partially overlaps with the orthographic projection of the first auxiliary cathode layer on the base substrate.

Optionally, the display panel further comprises a second signal line layer comprising a third auxiliary cathode layer; wherein the anode material layer is on a side of the second signal line layer away from the base substrate; the anode material layer comprising a second auxiliary cathode layer; and the cathode layer is connected to the third auxiliary cathode layer sequentially through the first auxiliary cathode layer and the second auxiliary cathode layer.

In another aspect, the present disclosure provides a display panel, comprising a plurality of islands, and a plurality of bridges connecting the plurality of islands; wherein a respective one of the plurality of islands comprises at least one of a plurality of light emitting elements; the display panel comprises a plurality of first auxiliary cathode layers in the plurality of islands, respectively; the plurality of first auxiliary cathode layers are spaced apart from each other; a respective island of the plurality of islands comprises one or more first auxiliary cathode layers of the plurality of first auxiliary cathode layers; the one or more first auxiliary cathode layers in the respective island are spaced apart from each other; first auxiliary cathode layers in adjacent islands are spaced apart from each other by a first distance; the one or more first auxiliary cathode layers in the respective island are spaced apart from each other by a second distance; and the first distance is greater than the second distance.

In another aspect, the present disclosure provides a display apparatus, comprising the display panel described herein or fabricated by a method described herein, and one or more integrated circuits connected to the display panel.

In another aspect, the present disclosure provides a method of fabricating a display panel, comprising forming an anode material layer comprising an anode of a light emitting element on a base substrate; forming a pixel definition layer on a side of the anode material layer away from the base substrate, and defining a subpixel aperture; forming a first auxiliary cathode layer on a side of the pixel definition layer away from the base substrate; forming an organic material layer at least partially in the subpixel aperture and on a side of the anode away from the base substrate; and forming a cathode layer on a side of the organic material layer away from the base substrate; wherein the first auxiliary cathode layer is connected to the cathode layer; the first auxiliary cathode layer comprises a conductive material; and an orthographic projection of the first auxiliary cathode layer on the base substrate at least partially overlaps with an orthographic projection of the pixel definition layer on the base substrate.

### BRIEF DESCRIPTION OF THE FIGURES

The following drawings are merely examples for illustrative purposes according to various disclosed embodiments and are not intended to limit the scope of the present invention.

FIG. 1 is a schematic diagram illustrating the structure of a portion of a display panel in some embodiments according to the present disclosure.

FIG. 2 is a schematic diagram illustrating the structure of a portion of a display panel in some embodiments according to the present disclosure.

FIG. 3 is a plan view of two adjacent islands connected by a bridge in a portion of a display panel in some embodiments according to the present disclosure.

FIG. 4 is a cross-sectional view along an A-A′ line in FIG. 3.

FIG. 5 is a plan view of two adjacent islands connected by a bridge in a portion of a display panel in some embodiments according to the present disclosure.

FIG. 6 is a cross-sectional view along a B-B′ line in FIG. 5.

FIG. 7 is a cross-section view of a portion of a display panel in some embodiments according to the present disclosure.

FIG. 8 is a schematic diagram illustrating overlapping between an orthographic projection of a cathode layer and an orthographic projection of a first auxiliary cathode layer in some embodiments according to the present disclosure.

FIG. 9 is a schematic diagram illustrating overlapping between an orthographic projection of an organic material layer and an orthographic projection of a first auxiliary cathode layer in some embodiments according to the present disclosure.

FIG. 10 is a schematic diagram illustrating the structure of a first auxiliary cathode layer in some embodiments according to the present disclosure.

FIG. 11 is a plan view of an island in a portion of a display panel in some embodiments according to the present disclosure.

FIG. 12 is a plan view of an island in a portion of a display panel in some embodiments according to the present disclosure.

FIG. 13 is a plan view of an island in a portion of a display panel in some embodiments according to the present disclosure.

FIG. 14 is a schematic diagram illustrating the structure of a portion of a display panel in some embodiments according to the present disclosure.

FIG. 15A to FIG. 15M illustrate a process of fabricating a display panel in some embodiments according to the present disclosure.

FIG. 16A to FIG. 16U illustrate a process of fabricating a display panel in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

The present disclosure provides, inter alia, a display panel, a display apparatus, and a method of fabricating a display panel that substantially obviate one or more of the problems due to limitations and disadvantages of the related art. In one aspect, the present disclosure provides a display panel. In some embodiments, the display panel includes a base substrate; an anode material layer comprising an anode of a light emitting element on the base substrate; a pixel definition layer on a side of the anode material layer away from the base substrate, and defining a subpixel aperture; an organic material layer at least partially in the subpixel aperture and on a side of the anode away from the base substrate; a cathode layer on a side of the organic material layer away from the base substrate; and a first auxiliary cathode layer on a side of the pixel definition layer away from the base substrate. Optionally, the first auxiliary cathode layer is connected to the cathode layer. Optionally, the first auxiliary cathode layer comprises a conductive material. Optionally, an orthographic projection of the first auxiliary cathode layer on the base substrate at least partially overlaps with an orthographic projection of the pixel definition layer on the base substrate.

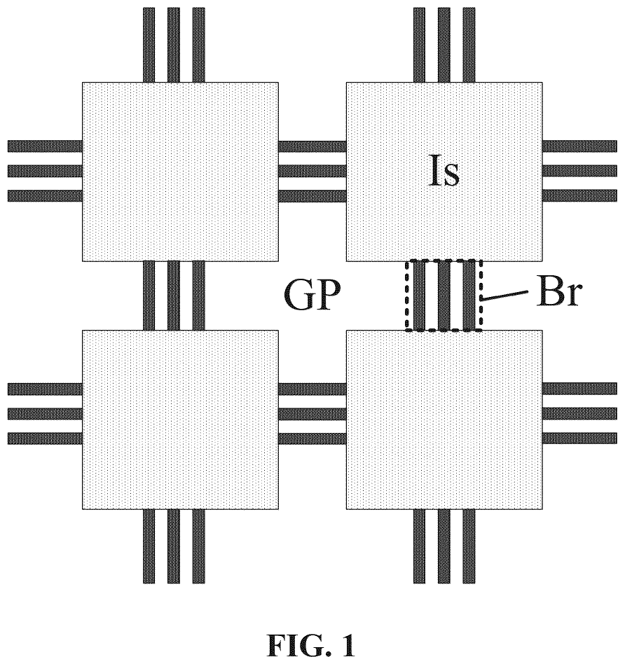

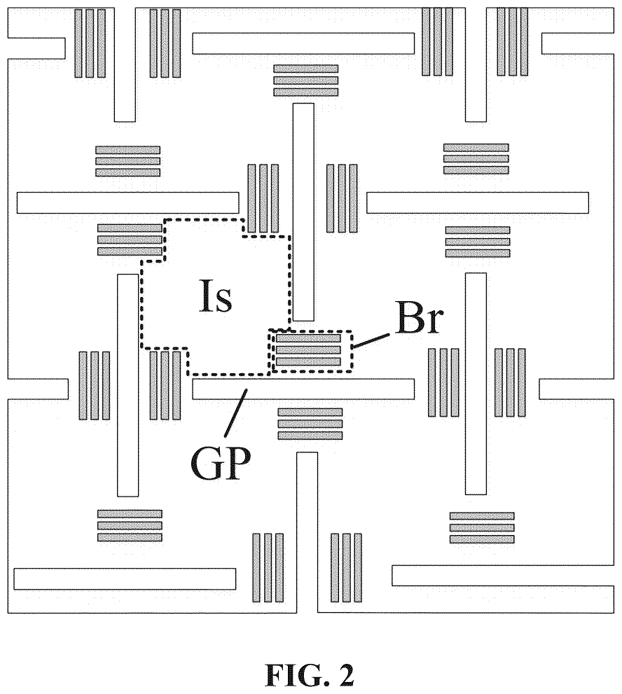

FIG. 1 is a schematic diagram illustrating the structure of a portion of a display panel in some embodiments according to the present disclosure. FIG. 2 is a schematic diagram illustrating the structure of a portion of a display panel in some embodiments according to the present disclosure. Referring to FIG. 1 and FIG. 2, in some embodiments, the display panel includes a plurality of islands Is; and a plurality of bridges Br connecting the plurality of islands Is. Optionally, the display panel has a plurality of gaps GP respectively between adjacent bridges of the plurality of bridges Br (or between adjacent islands of the plurality of islands Is, or between a bridge of the plurality of bridges Br and an island of the plurality of islands Is). Optionally, the plurality of gaps GP are carved-out regions in which any material (e.g., a flexible base substrate and any layer on the flexible base substrate) of the stretchable display panel is absent.

In some embodiments, the display panel is a stretchable display panel. As used herein, the term “stretchable” refers to the ability of a material, structure, device or device component to be strained in tension (e.g., being made longer and/or wider) without undergoing permanent deformation or failure such as fracture, e.g., the ability to elongate at least 10% of its length without permanently deforming, tearing, or breaking. The term is also meant to encompass substrates having components (whether or not the components themselves are individually stretchable as stated above) that are configured in such a way so as to accommodate a stretchable, inflatable, or expandable surface and remain functional when applied to a stretchable, inflatable, or otherwise expandable surface that is stretched, inflated, or otherwise expanded respectively. The term is also meant to encompass substrates that may be elastically and/or plastically deformable (i.e. after being stretched, the substrate may return to its original size when the stretching force is released or the substrate may not return to its original size and in some examples, may remain in the stretched form) and the deformation (i.e. stretching and optionally flexing) may occur during manufacture of the substrate (e.g. with the substrate being stretched and optionally flexed to form its final shape), during assembly of a device incorporating the substrate (which may be considered part of the manufacturing operation) and/or during use (e.g. with the user being able to stretch and optionally flex the substrate).

In some embodiments, a respective one of the plurality of islands Is includes at least one of a plurality of light emitting elements encapsulated therein. Optionally, the display panel in the respective one of the plurality of islands Is includes a single one light emitting element of the plurality of light emitting elements. Optionally, the stretchable display panel in the respective one of the plurality of islands Is includes multiple light emitting elements of the plurality of light emitting elements. Optionally, the respective one of the plurality of islands Is includes a red light emitting element, a green light emitting element, and a blue light emitting element of the plurality of light emitting elements.

Various appropriate light emitting elements may be used in the present stretchable display panel. Examples of appropriate light emitting elements include an organic light emitting diode, a quantum dots light emitting diode, and a micro light emitting diode.

In some embodiments, the display panel further includes a plurality of driving circuits for driving light emission of the plurality of light emitting elements. The plurality of driving circuits includes a plurality of thin film transistors respectively in the plurality of islands Is, and a plurality of signal lines at least partially in the plurality of bridges Br. The plurality of signal lines are configured to transmit signals into or out from a respective one of the plurality of islands Is. Examples of the plurality of signal lines include gate lines, data lines, common electrode signal lines, power signal lines, clock signal lines, and so on. Optionally, the plurality of signal lines are a plurality of flexible signal lines. Various appropriate materials may be used for making the plurality of signal lines. Examples of appropriate conductive materials for making the plurality of signal lines include metals, alloys, graphene, carbon nanotubes, flexible conductive polymers, and other flexible conductive materials. For example, in some embodiments, the plurality of signal lines are made of one or a combination of a liquid metal, carbon nanotubes, graphene, and silver nanowires.

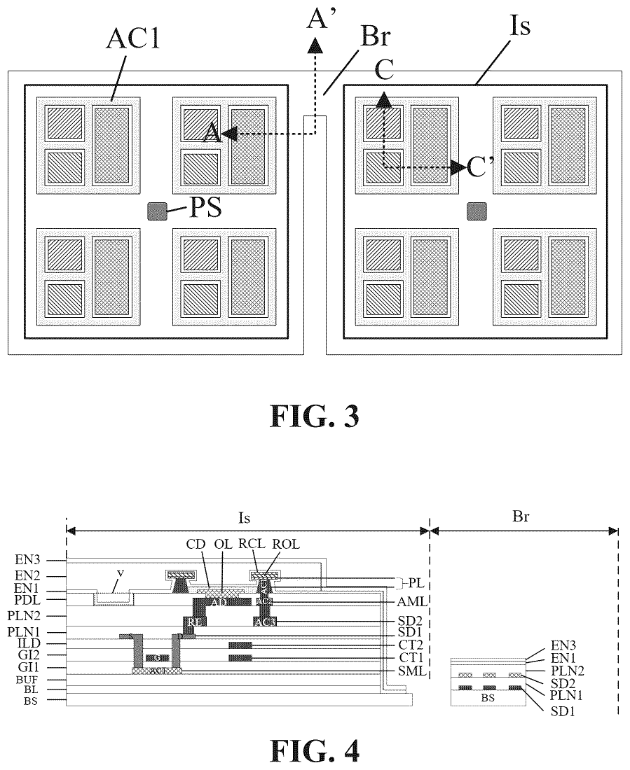

FIG. 3 is a plan view of two adjacent islands connected by a bridge in a portion of a display panel in some embodiments according to the present disclosure. Referring to FIG. 3, two adjacent islands of the plurality of islands Is are connected by a bridge of the plurality of bridges Br. The display panel further includes a plurality of spacers PS. Optionally, the display panel includes at least one spacer of the plurality of spacers PS in a respective island of the plurality of islands Is. The inventors of the present disclosure discover that, by having the plurality of spacers PS, the first auxiliary cathode layer AC1 can be protected. Because a height of the plurality of spacers PS is greater than a height of the first auxiliary cathode layer AC1, the plurality of spacers PS prevent deformation or damage to the first auxiliary cathode layer AC1 under compressive stress.

In alternative embodiments, the display panel is absent of any spacer. The inventors of the present disclosure discover that, a display panel free of spacers can save space and achieve a higher resolution.

FIG. 4 is a cross-sectional view along an A-A′ line in FIG. 3. Referring to FIG. 3 and FIG. 4, a respective bridge of the plurality of bridges Br includes a base substrate BS, a first signal line layer SD1 on the base substrate BS, a first planarization layer PLN1 on a side of the first signal line layer SD1 away from the base substrate BS, a second signal line layer SD2 on a side of the first planarization layer PLN1 away from the base substrate BS, a second planarization layer PLN2 on a side of the second signal line layer SD2 away from the base substrate BS, a first encapsulating sub-layer EN1 on a side of the second planarization layer PLN2 away from the base substrate BS, and a third encapsulating sub-layer EN3 on a side of the first encapsulating sub-layer EN1 away from the base substrate BS. Optionally, the first encapsulating sub-layer EN1 includes an inorganic material, and the third encapsulating sub-layer EN3 includes an inorganic material.

In some embodiments, the base substrate BS is a flexible base substrate. Various appropriate elastomer polymer materials may be used for making the base substrate BS. Examples of appropriate elastomer polymers include polyimides, polysilicones, polysiloxanes, polyepoxides, silicone-based polymers (e.g., polydimethylsiloxane-based materials such as poly dimethylsiloxane, hexamethyldisiloxane, and polyphenylmethylsiloxane), polyurethane-based materials (such as polyurethane, polyurethane acrylate, polyether urethane, and polycarbonate-polyurethane elastomers), polyvinylfluoride, polyvinylchloride, acrylate polymer, acrylate terpolymer, rubbers (e.g., chloroprene rubber, acryl-based rubber, and nitrile rubber), polyvinylpyrrolidone, polyvinyl alcohol, polymethyl methacrylate, cellulose acetate, cellulose acetate butyrate, cellulose acetate propionate, polymethyl acrylate, polyvinyl acetate, polyacrylonitrile, polyfurfuryl alcohol, polystyrene, polyethylene oxide, polypropylene oxide, polycarbonate, polyvinyl chloride, polycaprolactone, and any combination thereof.

In some embodiments, a respective island of the plurality of islands Is includes a base substrate BS, a barrier layer BL on the base substrate BS, a buffer layer BUF on a side of the barrier layer BL away from the base substrate BS, a semiconductor material layer SML on a side of the buffer layer BUF away from the base substrate BS, a first gate insulating layer GI1 on a side of the semiconductor material layer SML away from the base substrate BS, a first conductive layer CT1 on a side of the first gate insulating layer GI1 away from the base substrate BS, a second gate insulating layer GI2 on a side of the first conductive layer CT1 away from the base substrate BS, a second conductive layer CT2 on a side of the second gate insulating layer GI2 away from the base substrate BS, an inter-layer dielectric layer ILD on a side of the second conductive layer CT2 away from the base substrate BS, a first signal line layer SD1 on a side of the inter-layer dielectric layer ILD away from the base substrate BS, a first planarization layer PLN1 on a side of the first signal line layer SD1 away from the base substrate BS, a second signal line layer SD2 on a side of the first planarization layer PLN1 away from the base substrate BS, a second planarization layer PLN2 on a side of the second signal line layer SD2 away from the base substrate BS, an anode material layer AML on a side of the second planarization layer PLN2 away from the base substrate BS, a pixel definition layer PDL on a side of the anode material layer AML away from the base substrate BS and defining a subpixel aperture, an organic material layer OL at least partially in the subpixel aperture and on a side of an anode AD away from the base substrate BS, a cathode layer CD on a side of the organic material layer OL away from the base substrate BS, a pillar layer PL on a side of the pixel definition layer PDL away from the base substrate BS, a residual organic material layer ROL on a side of the pillar layer PL away from the base substrate BS, a residual cathode material layer RCL on a side of the residual organic material layer ROL away from the base substrate BS, a first encapsulating sub-layer EN1 on a side of the cathode layer CD, the residual cathode material layer RCL, and the pixel definition layer PDL away from the base substrate BS, a second encapsulating sub-layer EN2 on a side of the first encapsulating sub-layer EN1 away from the base substrate BS, and a third encapsulating sub-layer EN3 on a side of the second encapsulating sub-layer EN2 away from the base substrate BS.

In some embodiments, the organic material layer OL includes a light emitting layer, e.g., a red light emitting layer, a green light emitting layer, or a blue light emitting layer. In some embodiments, the organic material layer OL includes an organic functional material layer. Examples of organic functional material layers include a bole injection layer, a hole transport layer, an electron injection layer, an electron transport layer, and a charge generation layer.

In some embodiments, the semiconductor material layer SML includes an active layer ACT of a transistor in the respective island. The first conductive layer CT1 includes a gate electrode G of the transistor. The first signal line layer SD1 includes a first electrode S and a second electrode D of the transistor. In some embodiments, the second signal line layer SD2 includes a relay electrode RE connecting an anode AD of a respective light emitting element in the respective island with the second electrode D of the transistor. In some embodiments, the second signal line layer SD2 further includes a third auxiliary cathode layer AC3, the third auxiliary cathode layer AC3 electrically connected to the cathode layer CD. In some embodiments, the anode material layer AML includes the anode AD of the respective light emitting element, and a second auxiliary cathode layer AC2. The second auxiliary cathode layer AC2 connected to the third auxiliary cathode layer AC3, e.g., through a via extending through the second planarization layer PLN2. In some embodiments, the pillar layer PL includes a first auxiliary cathode layer AC1, the first auxiliary cathode layer AC1 connected to the second auxiliary cathode layer AC2, e.g., through a via extending through the pixel definition layer PDL. In some embodiments, the second auxiliary cathode layer AC2 and/or the third auxiliary cathode layer AC3 are connected to a low voltage signal supply line located in a peripheral region of the display panel. In some embodiments, the second auxiliary cathode layer AC2 and/or the third auxiliary cathode layer AC3 are connected to the low voltage signal supply line in the peripheral region through one or more signal lines in the plurality of bridges.

In some embodiments, an orthographic projection of the third auxiliary cathode layer AC3 on a base substrate BS is substantially non-overlapping (e.g., at least 70% non-overlapping, at least 75% non-overlapping, at least 80% non-overlapping, at least 85% non-overlapping, at least 90% non-overlapping, at least 95% non-overlapping, at least 99% non-overlapping, or completely non-overlapping) with an orthographic projection of the second conductive layer CT2 on the base substrate BS. In some embodiments, an orthographic projection of the second auxiliary cathode layer AC2 on a base substrate BS is substantially non-overlapping (e.g., at least 70% non-overlapping, at least 75% non-overlapping, at least 80% non-overlapping, at least 85% non-overlapping, at least 90% non-overlapping, at least 95% non-overlapping, at least 99% non-overlapping, or completely non-overlapping) with an orthographic projection of the second conductive layer CT2 on the base substrate BS. In some embodiments, an orthographic projection of the first auxiliary cathode layer AC1 on a base substrate BS is substantially non-overlapping (e.g., at least 70% non-overlapping, at least 75% non-overlapping, at least 80% non-overlapping, at least 85% non-overlapping, at least 90% non-overlapping, at least 95% non-overlapping, at least 99% non-overlapping, or completely non-overlapping) with an orthographic projection of the second conductive layer CT2 on the base substrate BS. The inventors of the present disclosure discover that this structure reduces parasitic capacitance between the second conductive layer CT2 and the auxiliary cathode structure.

In some embodiments, the display panel further includes a fourth auxiliary cathode layer in a layer different from the first auxiliary cathode layer AC1, the second auxiliary cathode layer AC2, and the third auxiliary cathode layer AC3. Optionally, the fourth auxiliary cathode layer is connected to the third auxiliary cathode layer AC3 through a via extending through one or more insulating layers. Optionally, the fourth auxiliary cathode layer is in the second conductive layer CT2.

In some embodiments, the display panel further includes a fifth auxiliary cathode layer in a layer different from the first auxiliary cathode layer AC1, the second auxiliary cathode layer AC2, the third auxiliary cathode layer AC3, and the fourth auxiliary cathode layer. Optionally, the fifth auxiliary cathode layer is connected to the fourth auxiliary cathode layer through a via extending through one or more insulating layers. Optionally, the fifth auxiliary cathode layer is in the first conductive layer CT1.

In some embodiments, an orthographic projection of the second encapsulating sub-layer EN2 on a base substrate BS substantially covers (e.g., covers at least 70%, covers at least 75%, covers at least 80%, covers at least 85%, covers at least 90%, covers at least 95%, covers at least 99%, or completely covers) an orthographic projection of the third auxiliary cathode layer AC3 on the base substrate BS. Optionally, a distance between the third auxiliary cathode layer AC3 and an edge of the second encapsulating sub-layer EN2 is less than a distance between the third auxiliary cathode layer AC3 and a respective gap of the plurality of gaps closest to the edge of the second encapsulating sub-layer EN2.

In some embodiments, an orthographic projection of the second encapsulating sub-layer EN2 on a base substrate BS substantially covers (e.g., covers at least 70%, covers at least 75%, covers at least 80%, covers at least 85%, covers at least 90%, covers at least 95%, covers at least 99%, or completely covers) an orthographic projection of the second auxiliary cathode layer AC2 on the base substrate BS. Optionally, a distance between the second auxiliary cathode layer AC2 and an edge of the second encapsulating sub-layer EN2 is less than a distance between the second auxiliary cathode layer AC2 and a respective gap of the plurality of gaps closest to the edge of the second encapsulating sub-layer EN2.

In some embodiments, an orthographic projection of the second encapsulating sub-layer EN2 on a base substrate BS substantially covers (e.g., covers at least 70%, covers at least 75%, covers at least 80%, covers at least 85%, covers at least 90%, covers at least 95%, covers at least 99%, or completely covers) an orthographic projection of the first auxiliary cathode layer AC1 on the base substrate BS. Optionally, a distance between the first auxiliary cathode layer AC1 and an edge of the second encapsulating sub-layer EN2 is less than a distance between the first auxiliary cathode layer AC1 and a respective gap of the plurality of gaps closest to the edge of the second encapsulating sub-layer EN2.

Various appropriate materials may be used for making the first auxiliary cathode layer AC1. For example, a conductive material may be deposited on the substrate by a sputtering process and patterned. Examples of appropriate conductive materials for making the first auxiliary cathode layer AC1 include, but are not limited to, titanium, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. In some embodiments, the first auxiliary cathode layer AC1 includes a plurality of sub-layers stacked together. In one example, the first auxiliary cathode layer AC1 includes a stacked titanium/aluminum/titanium multi-layer structure. In another example, the first signal line layer includes a stacked molybdenum/aluminum/molybdenum multi-layer structure.

Various appropriate materials may be used for making the second auxiliary cathode layer AC2. For example, a conductive material may be deposited on the substrate by a sputtering process and patterned. Examples of appropriate conductive materials for making the second auxiliary cathode layer AC2 include, but are not limited to, titanium, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like.

Various appropriate materials may be used for making the third auxiliary cathode layer AC3. For example, a conductive material may be deposited on the substrate by a sputtering process and patterned. Examples of appropriate conductive materials for making the third auxiliary cathode layer AC3 include, but are not limited to, titanium, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like.

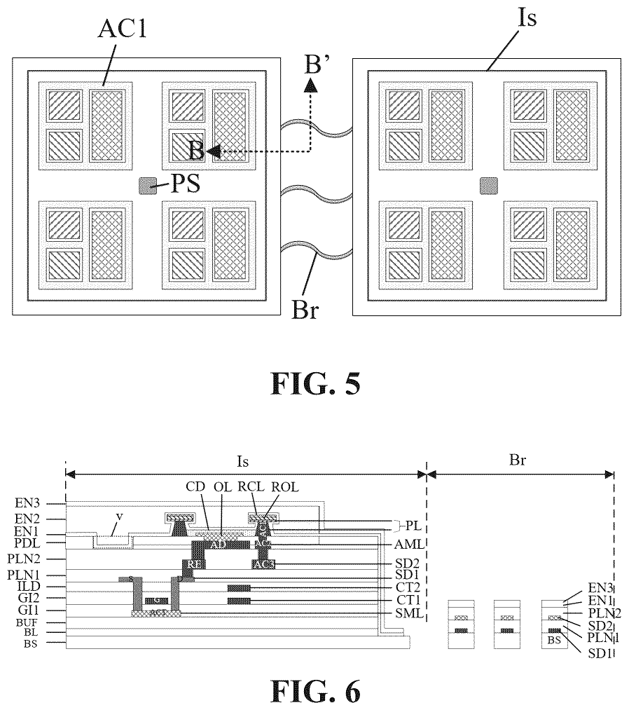

FIG. 5 is a plan view of two adjacent islands connected by a bridge in a portion of a display panel in some embodiments according to the present disclosure. FIG. 6 is a cross-sectional view along a B-B′ line in FIG. 5. Referring to FIG. 5 and FIG. 6, in some embodiments, the plurality of bridges Br are a plurality of curved bridges.

Various appropriate implementations of the plurality of bridges Br may be practiced in the present disclosure. In some embodiments, a respective bridge of the plurality of bridges Br includes a single layer of signal lines. In alternative embodiments, a respective bridge of the plurality of bridges Br includes signal lines in multiple layers, e.g., in two layers, in three layers, etc. In some embodiments, an orthographic projection of a signal line in a first layer in the respective bridge on the base substrate is at least partially non-overlapping (e.g., completely non-overlapping) with an orthographic projection of signal lines in other layers in the respective bridge on the base substrate.

In some embodiments, referring to FIG. 3 to FIG. 6, a respective bridge of the plurality of bridges Br includes one or more first signal lines in the first signal line layer SD1 and one or more second signal lines in the second signal line layer SD2. In some embodiments, an orthographic projection of the one or more first signal lines on a base substrate BS at least partially overlaps with an orthographic projection of the one or more second signal lines on the base substrate BS. In some embodiments, a line width of a respective second signal line of the one or more second signal lines is greater than a line width of a respective first signal line of the one or more first signal lines. In some embodiments, an orthographic projection of the respective second signal line on a base substrate BS substantially covers (e.g., covers at least 70%, covers at least 75%, covers at least 80%, covers at least 85%, covers at least 90%, covers at least 95%, covers at least 99%, or completely covers) an orthographic projection of the respective first signal line on the base substrate BS.

Referring to FIG. 4 and FIG. 6, the display panel in some embodiments further includes a via v extending through the pixel definition layer PDL. Optionally, at least a portion of the first encapsulating sub-layer EN1 and/or at least a portion of the second encapsulating sub-layer EN2 extend into the via v. Optionally, the via v is a gas releasing via configured to release a gas in the process of fabricating the display panel. In some embodiments, a shortest distance between the first auxiliary cathode layer AC1 and the via v is greater than a shortest distance between the first auxiliary cathode layer AC1 and the anode AD.

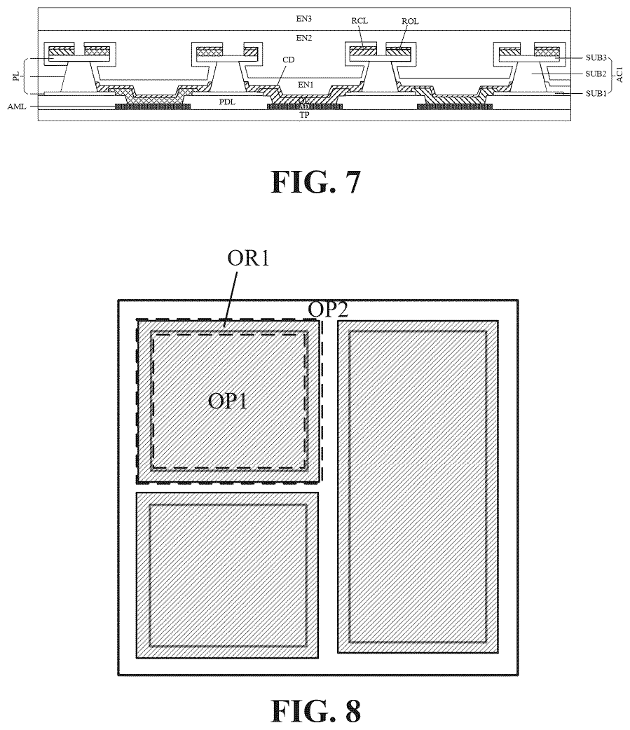

FIG. 7 is a cross-section view of a portion of a display panel in some embodiments according to the present disclosure. For example, FIG. 7 may be a cross-section of a portion of the display panel along a C-C′ line depicted in FIG. 3. Referring to FIG. 7, a respective island of the plurality of islands of the display panel in some embodiments includes multiple subpixels, each subpixel having a light emitting element. The light emitting element includes an anode AD, an organic material layer OL on the anode AD, and a cathode layer CD on a side of the organic material layer OL away from the anode AD.

In some embodiments, the display panel includes a transistor plate TP, an anode material layer AML on the transistor plate TP, a pixel definition layer PDL on a side of the anode material layer AML away from the transistor plate TP and defining a subpixel aperture, an organic material layer OL at least partially in the subpixel aperture and on a side of an anode AD away from the transistor plate TP, a cathode layer CD on a side of the organic material layer OL away from the transistor plate TP, a pillar layer PL on a side of the pixel definition layer PDL away from the transistor plate TP, a residual organic material layer ROL on a side of the pillar layer PL away from the transistor plate TP, a residual cathode material layer RCL on a side of the residual organic material layer ROL away from the second planarization layer PLN2, a first encapsulating sub-layer EN1 on a side of the cathode layer CD, the residual cathode material layer RCL, and the pixel definition layer PDL away from the second planarization layer PLN2, a second encapsulating sub-layer EN2 on a side of the first encapsulating sub-layer EN1 away from the second planarization layer PLN2, and a third encapsulating sub-layer EN3 on a side of the second encapsulating sub-layer EN2 away from the second planarization layer PLN2. The transistor plate TP includes a plurality of transistors. In one example, the transistor plate TP includes layers from the base substrate BS to the second planarization layer PLN2 depicted in FIG. 4 and FIG. 6.

In some embodiments, the first auxiliary cathode layer AC1 includes a plurality of sub-layers stacked together. In some embodiments, the first auxiliary cathode layer AC1 includes a first sub-layer SUB1, a second sub-layer SUB2 on the first sub-layer SUB1, and a third sub-layer SUB3 on a side of the second sub-layer SUB2 away from the first sub-layer SUB1. In one example, the first sub-layer SUB1 includes titanium, the second sub-layer SUB2 includes aluminum, and the third sub-layer SUB3 includes titanium.

In some embodiments, an orthographic projection of the first auxiliary cathode layer AC1 on a base substrate at least partially overlaps with an orthographic projection of the pixel definition layer PDL on the base substrate. Optionally, the orthographic projection of the pixel definition layer PDL on the base substrate substantially covers (e.g., covers at least 70%, covers at least 75%, covers at least 80%, covers at least 85%, covers at least 90%, covers at least 95%, covers at least 99%, or completely covers) the orthographic projection of the first auxiliary cathode layer AC1 on the base substrate.

In some embodiments, the first auxiliary cathode layer AC1 is in direct contact with the pixel definition layer PDL. Optionally, the first sub-layer SUB1 of the first auxiliary cathode layer AC1 is in direct contact with the pixel definition layer PDL.

In some embodiments, an orthographic projection of the cathode layer CD of a respective subpixel on a base substrate is between orthographic projections of two adjacent portions of the first auxiliary cathode layer AC1 on the base substrate. Optionally, the cathode layer CD of the respective subpixel is spaced apart from cathode layers of adjacent subpixels by a portion of the first auxiliary cathode layer AC1. In one particular example, cathode layers of a plurality of subpixels are spaced apart from each other, a respective cathode layer of a respective subpixel is electrically connected to, but not directly connected to cathode layers in adjacent subpixels. The cathode layer CD is disconnected from the residual cathode layer RCL.

In some embodiments, an orthographic projection of the organic material layer OL of a respective subpixel on a base substrate is between orthographic projections of two adjacent portions of the first auxiliary cathode layer AC1 on the base substrate. Optionally, the organic material layer OL of the respective subpixel is spaced apart from organic material layers of adjacent subpixels by a portion of the first auxiliary cathode layer AC1. The organic material layer OL is disconnected from the residual organic material layer ROL.

In some embodiments, the first encapsulating sub-layer EN1 includes a plurality of first encapsulating blocks spaced apart from each other. In some embodiments, at least a portion of an orthographic projection of a respective first encapsulating block on a base substrate is between orthographic projections of two adjacent portions of the first auxiliary cathode layer AC1 on the base substrate.

In some embodiments, referring to FIG. 3 to FIG. 7, the orthographic projection of the first auxiliary cathode layer AC1 on the base substrate has a ring shape. In some embodiments, the orthographic projection of the first auxiliary cathode layer AC1 on the base substrate substantially surrounds (e.g., surrounds at least 70% of a periphery of, surrounds at least 75% of a periphery of, surrounds at least 80% of a periphery of, surrounds at least 85% of a periphery of, surrounds at least 90% of a periphery of, surrounds at least 95% of a periphery of, surrounds at least 99% of a periphery of, or completely surrounds a periphery of) at least a portion of an orthographic projection of the organic material layer OL on the base substrate. Optionally, the orthographic projection of the first auxiliary cathode layer AC1 on the base substrate substantially surrounds (e.g., surrounds at least 70% of a periphery of, surrounds at least 75% of a periphery of, surrounds at least 80% of a periphery of, surrounds at least 85% of a periphery of, surrounds at least 90% of a periphery of, surrounds at least 95% of a periphery of, surrounds at least 99% of a periphery of, or completely surrounds a periphery of) at least a portion of an orthographic projection of the cathode layer CD on the base substrate. the orthographic projection of the first auxiliary cathode layer AC1 on the base substrate substantially surrounds (e.g., surrounds at least 70% of a periphery of, surrounds at least 75% of a periphery of, surrounds at least 80% of a periphery of, surrounds at least 85% of a periphery of, surrounds at least 90% of a periphery of, surrounds at least 95% of a periphery of, surrounds at least 99% of a periphery of, or completely surrounds a periphery of) at least a portion of an orthographic projection of the anode AD on the base substrate.

In some embodiments, the orthographic projection of the first auxiliary cathode layer AC1 on the base substrate has a ring shape comprising connected multiple rings having multiple openings. A respective ring of the connected multiple rings substantially surrounds (e.g., surrounds at least 70% of a periphery of, surrounds at least 75% of a periphery of, surrounds at least 80% of a periphery of, surrounds at least 85% of a periphery of, surrounds at least 90% of a periphery of, surrounds at least 95% of a periphery of, surrounds at least 99% of a periphery of, or completely surrounds a periphery of) at least a portion of an orthographic projection of the organic material layer OL in a respective light emitting element of multiple light emitting elements on the base substrate. Optionally, the respective ring substantially surrounds (e.g., surrounds at least 70% of a periphery of, surrounds at least 75% of a periphery of, surrounds at least 80% of a periphery of, surrounds at least 85% of a periphery of, surrounds at least 90% of a periphery of, surrounds at least 95% of a periphery of, surrounds at least 99% of a periphery of, or completely surrounds a periphery of) at least a portion of an orthographic projection of the cathode layer CD in a respective light emitting element of multiple light emitting elements on the base substrate. Optionally, the respective ring substantially surrounds (e.g., surrounds at least 70% of a periphery of, surrounds at least 75% of a periphery of, surrounds at least 80% of a periphery of, surrounds at least 85% of a periphery of, surrounds at least 90% of a periphery of, surrounds at least 95% of a periphery of, surrounds at least 99% of a periphery of, or completely surrounds a periphery of) at least a portion of an orthographic projection of the anode AD in a respective light emitting element of multiple light emitting elements on the base substrate.

An orthographic projection of the second auxiliary cathode layer AC2 on the base substrate BS may have various appropriate shapes. In some embodiments, the orthographic projection of the second auxiliary cathode layer AC2 on the base substrate BS has a grid shape. In alternative embodiments, the orthographic projection of the second auxiliary cathode layer AC2 on the base substrate BS has a ring shape. Optionally, the orthographic projection of the second auxiliary cathode layer AC2 on the base substrate BS has a ring shape comprising connected multiple rings having multiple openings.

An orthographic projection of the third auxiliary cathode layer AC3 on the base substrate BS may have various appropriate shapes. In some embodiments, the orthographic projection of the third auxiliary cathode layer AC3 on the base substrate BS has a grid shape. In alternative embodiments, the orthographic projection of the third auxiliary cathode layer AC3 on the base substrate BS has a ring shape. Optionally, the orthographic projection of the third auxiliary cathode layer AC3 on the base substrate BS has a ring shape comprising connected multiple rings having multiple openings.

FIG. 8 is a schematic diagram illustrating overlapping between an orthographic projection of a cathode layer and an orthographic projection of a first auxiliary cathode layer in some embodiments according to the present disclosure. Referring to FIG. 3 to FIG. 8, in some embodiments, an orthographic projection OP1 of the cathode layer CD on a base substrate BS at least partially (e.g., at least 1%, at least 2%, at least 3%, at least 4%, at least 5%, at least 6%, at least 7%, at least 8%, at least 9%, or at least 10%) overlaps with an orthographic projection OP2 of the first auxiliary cathode layer AC1 on the base substrate BS. In some embodiments, the orthographic projection OP1 of the cathode layer CD on the base substrate BS overlaps with the orthographic projection OP2 of the first auxiliary cathode layer AC1 on the base substrate BS, forming a first overlapping region OR1. In some embodiments, the first overlapping region OR1 has a ring shape. As used herein. the term “ring” or “ring structure” refers to a structure or portion of a structure having a hole there through, including but not limited to a ring or doughnut shape. A ring structure may be essentially round like a doughnut, or may be formed of a square, triangle or another shape with a hole there through. As used herein, a ring structure does not require that the ring shape be unbroken, and the term is intended to encompass structures that are substantially closed, but that comprise a break or a gap in the ring shape. The term encompasses structures that comprise cavity, e.g., a “C” and “U”-shaped cavity. A ring structure may consist essentially of a single ring, or it may be a component of a larger structure having additional features, e.g., additional ring structures, or non-ring-shaped features such as corners, points, strings, etc. In some embodiments, the first overlapping region OR1 substantially surrounds (e.g., surrounds at least 70% of a periphery of, surrounds at least 75% of a periphery of, surrounds at least 80% of a periphery of, surrounds at least 85% of a periphery of, surrounds at least 90% of a periphery of, surrounds at least 95% of a periphery of, surrounds at least 99% of a periphery of, or completely surrounds a periphery of) at least a portion of an orthographic projection of the organic material layer OL on the base substrate BS. In some embodiments, the first overlapping region OR1 substantially surrounds (e.g., surrounds at least 70% of a periphery of, surrounds at least 75% of a periphery of, surrounds at least 80% of a periphery of, surrounds at least 85% of a periphery of, surrounds at least 90% of a periphery of, surrounds at least 95% of a periphery of, surrounds at least 99% of a periphery of, or completely surrounds a periphery of) at least a portion of an orthographic projection of the anode AD on the base substrate BS.

In some embodiments, the cathode layer CD is in direct contact with the first auxiliary cathode layer AC1, e.g., in a region corresponding to the first overlapping region OR1. In some embodiments, the cathode layer CD is in direct contact with the first sub-layer SUB1. In some embodiments, the cathode layer CD is in direct contact with the second sub-layer SUB2. In some embodiments, the cathode layer CD is in direct contact with the first sub-layer SUB1, and in direct contact with the second sub-layer SUB2.

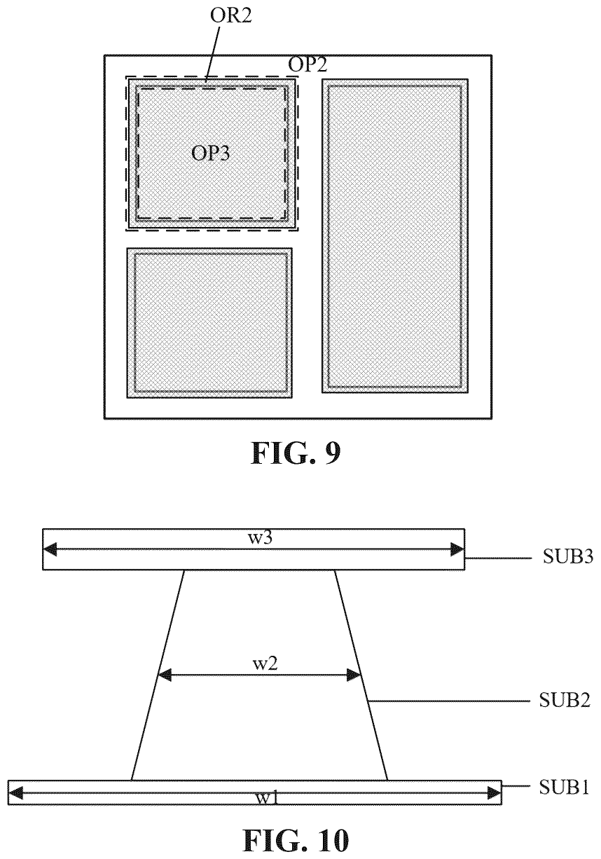

FIG. 9 is a schematic diagram illustrating overlapping between an orthographic projection of an organic material layer and an orthographic projection of a first auxiliary cathode layer in some embodiments according to the present disclosure. Referring to FIG. 3 to FIG. 7, and FIG. 9, in some embodiments, an orthographic projection OP3 of the organic material layer OL on a base substrate BS at least partially (e.g., at least 1%, at least 2%, at least 3%, at least 4%, at least 5%, at least 6%, at least 7%, at least 8%, at least 9%, or at least 10%) overlaps with an orthographic projection OP2 of the first auxiliary cathode layer AC1 on the base substrate BS. In some embodiments, the orthographic projection OP3 of the organic material layer OL on the base substrate BS overlaps with the orthographic projection OP2 of the first auxiliary cathode layer AC1 on the base substrate BS, forming a second overlapping region OR2. In some embodiments, the second overlapping region OR2 bas a ring shape. In some embodiments, the second overlapping region OR2 substantially surrounds (e.g., surrounds at least 70% of a periphery of, surrounds at least 75% of a periphery of, surrounds at least 80% of a periphery of, surrounds at least 85% of a periphery of, surrounds at least 90% of a periphery of, surrounds at least 95% of a periphery of, surrounds at least 99% of a periphery of, or completely surrounds a periphery of) at least a portion of an orthographic projection of the anode AD on the base substrate BS. In some embodiments, the second overlapping region OR2 substantially surrounds (e.g., surrounds at least 70% of a periphery of, surrounds at least 75% of a periphery of, surrounds at least 80% of a periphery of, surrounds at least 85% of a periphery of, surrounds at least 90% of a periphery of, surrounds at least 95% of a periphery of, surrounds at least 99% of a periphery of, or completely surrounds a periphery of) at least a portion of an orthographic projection of the cathode layer CD on the base substrate BS.

In some embodiments, the organic material layer OL is in direct contact with the first auxiliary cathode layer AC1, e.g., in a region corresponding to the second overlapping region OR2. In some embodiments, the organic material layer OL is in direct contact with the first sub-layer SUB1.

FIG. 10 is a schematic diagram illustrating the structure of a first auxiliary cathode layer in some embodiments according to the present disclosure. Referring to FIG. 7 and FIG. 10, in some embodiments, the first sub-layer SUB1 has a first width w1 along a plane intersecting with the first auxiliary cathode layer AC1 and two adjacent light emitting elements in two adjacent subpixels, respectively, and perpendicular to the base substrate BS. The second sub-layer SUB2 has a second width w2 along the plane intersecting with the first auxiliary cathode layer AC1 and two adjacent light emitting elements in two adjacent subpixels, respectively, and perpendicular to the base substrate BS. The third sub-layer SUB3 has a third width w3 along a plane intersecting with the first auxiliary cathode layer AC1 and two adjacent light emitting elements in two adjacent subpixels, respectively, and perpendicular to the base substrate BS. In some embodiments, the first width w1 is greater than the second width w2, and the third width w3 is greater than the second width w2.

In some embodiments, an orthographic projection of the first sub-layer SUB1 on the base substrate BS substantially covers (e.g., covers at least 70%, covers at least 75%, covers at least 80%, covers at least 85%, covers at least 90%, covers at least 95%, covers at least 99%, or completely covers) an orthographic projection of the second sub-layer SUB2 on the base substrate BS. In some embodiments, an orthographic projection of the third sub-layer SUB3 on the base substrate BS substantially covers (e.g., covers at least 70%, covers at least 75%, covers at least 80%, covers at least 85%, covers at least 90%, covers at least 95%, covers at least 99%, or completely covers) an orthographic projection of the second sub-layer SUB2 on the base substrate BS.

In alternative embodiments, the first auxiliary cathode layer includes a second sub-layer SUB2 and a third sub-layer SUB3 on a side of the second sub-layer SUB2 away from the base substrate. In one example, the first auxiliary cathode layer is absent of a first sub-layer SUB1. In some embodiments, the second sub-layer SUB2 has a second width w2 along the plane intersecting with the first auxiliary cathode layer AC1 and two adjacent light emitting elements in two adjacent subpixels, respectively, and perpendicular to the base substrate BS. The third sub-layer SUB3 has a third width w3 along a plane intersecting with the first auxiliary cathode layer AC1 and two adjacent light emitting elements in two adjacent subpixels, respectively, and perpendicular to the base substrate BS. In some embodiments, the third width w3 is greater than the second width w2.

In some embodiments, an orthographic projection of the third sub-layer SUB3 on the base substrate BS substantially covers (e.g., covers at least 70%, covers at least 75%, covers at least 80%, covers at least 85%, covers at least 90%, covers at least 95%, covers at least 99%, or completely covers) an orthographic projection of the second sub-layer SUB2 on the base substrate BS.

Referring to FIG. 4, FIG. 6, and FIG. 7, in some embodiments, the cathode layer CD is connected to the first auxiliary cathode layer AC1, the first auxiliary cathode layer AC1 is connected to the second auxiliary cathode layer AC2, and the second auxiliary cathode layer AC2 is connected to the third auxiliary cathode layer AC3. In some embodiments, the third auxiliary cathode layer AC3 is in the second signal line layer SD2, the second auxiliary cathode layer AC2 is in the anode material layer AML on a side of the second signal line layer SD2 away from the base substrate BS, the first auxiliary cathode layer AC1 is in the pillar layer PL on a side of the anode material layer AML away from the base substrate BS. In one particular example, the first auxiliary cathode layer AC1 constitutes multiple layers of the pillar layer PL. In an alternative example the first auxiliary cathode layer AC1 constitutes a single layer of the pillar layer PL.

In related display panels, the highest pixel density for stretchable displays (approximately 20% stretch) can only reach up to 100 ppi. In contrast, for relatively high-resolution 200 ppi displays, the stretchability decreases to 1%, and they generally lack significant stretch capability. The inventors of the present disclosure discover that, as the resolution increases, the stretchability of stretchable displays significantly decreases. Due to the inherent size limitations of pixel structures themselves, the size of rigid islands cannot be infinitely small. Due to spatial constraints, it is challenging to improve both resolution and stretchability.

The inventors of the present disclosure discover that, by having a pillar layer comprising the first auxiliary cathode layer, the spacing distance between adjacent light emitting elements can be significantly reduced. The display panel according to the present disclosure can have an increased resolution without compromising the light emitting area and light emission efficiency.

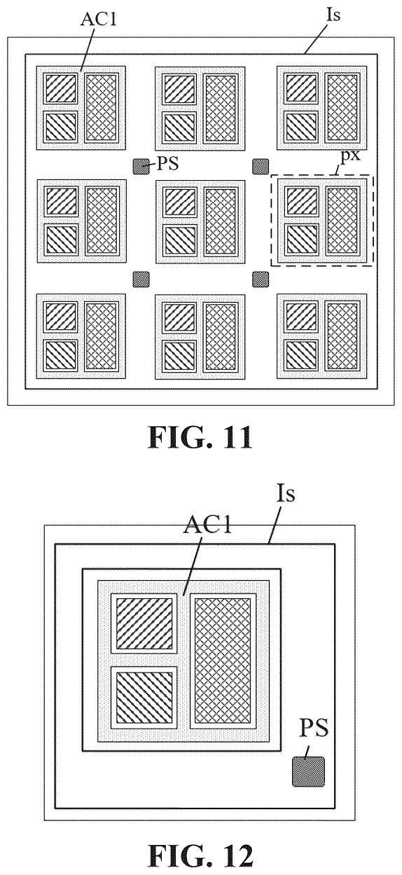

FIG. 11 is a plan view of an island in a portion of a display panel in some embodiments according to the present disclosure. Referring to FIG. 11, in some embodiments, a respective island of the plurality of islands Is includes multiple pixels px. A respective pixel of the multiple pixels px includes one or more subpixels, e.g., a red subpixel, a green subpixel, and a blue subpixel. In one example, the respective island includes nine pixels arranged in an array. In another example, the display panel having this structure can have a resolution of at least 300 ppi with a 9% stretchability.

FIG. 12 is a plan view of an island in a portion of a display panel in some embodiments according to the present disclosure. Referring to FIG. 12, in some embodiments, a respective island of the plurality of islands Is includes one pixel, the one pixel including one or more subpixels, e.g., a red subpixel, a green subpixel, and a blue subpixel. In some embodiments, the respective island includes one spacer of the plurality of spacers PS. In one example, the display panel having this structure can have a resolution of at least 200 ppi with a 5% stretchability.

In one particular example depicted in FIG. 12, the first auxiliary cathode layer AC1 surrounds a periphery of each subpixel (e.g., a red subpixel, a green subpixel, and a blue subpixel) of a pixel in a respective island.

In alternative examples, the first auxiliary cathode layer AC1 surrounds a periphery of a pixel in a respective island. However, the first auxiliary cathode layer AC1 is absent between adjacent subpixels in the pixel.

FIG. 13 is a plan view of an island in a portion of a display panel in some embodiments according to the present disclosure. Referring to FIG. 13, in some embodiments, a respective island of the plurality of islands Is includes one pixel, the one pixel including one or more subpixels, e.g., a red subpixel, a green subpixel, and a blue subpixel. In some embodiments, the respective island includes four spacer of the plurality of spacers PS. In one example, the display panel having this structure can have a resolution of at least 200 ppi with a 5% stretchability. In one particular example, the plurality of spacers PS are spaced apart from the first auxiliary cathode layer AC1 by a substantially the same distance.

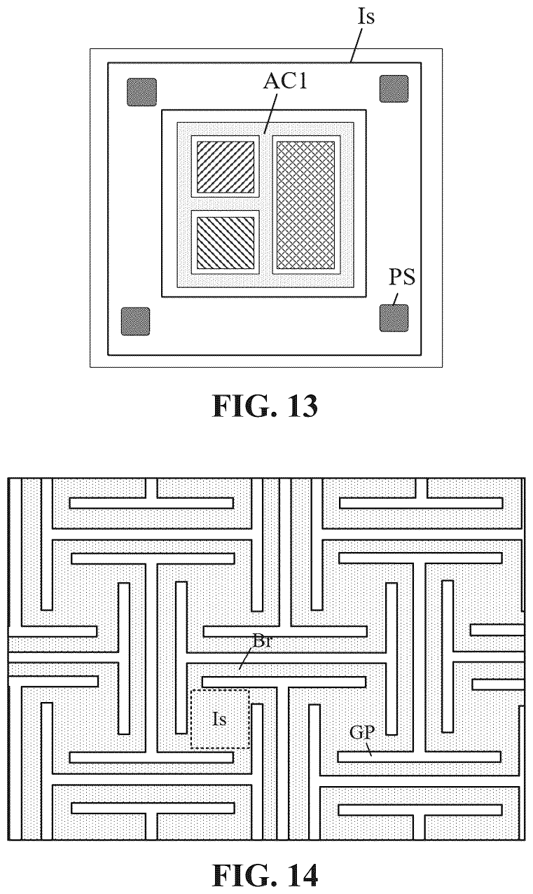

FIG. 14 is a schematic diagram illustrating the structure of a portion of a display panel in some embodiments according to the present disclosure. Referring to FIG. 14, in some embodiments, the display panel includes a plurality of islands Is; and a plurality of bridges Br connecting the plurality of islands Is. Optionally, the display panel has a plurality of gaps GP respectively between adjacent bridges of the plurality of bridges Br (or between adjacent islands of the plurality of islands Is, or between a bridge of the plurality of bridges Br and an island of the plurality of islands Is). Optionally, the plurality of gaps GP are carved-out regions in which any material (e.g., a flexible base substrate and any layer on the flexible base substrate) of the stretchable display panel is absent. In one example depicted in FIG. 14, a respective gap of the plurality of gaps GP has an H shape.

Referring to FIG. 3, FIG. 5, FIG. 11 to FIG. 13, in some embodiments, a respective spacer of the plurality of spacers PS is in an individual island of the plurality of islands Is. In some embodiments, an orthographic projection of the plurality of spacers PS on a base substrate is non-overlapping with an orthographic projection of the first auxiliary cathode layer AC1 on the base substrate. In some embodiments, the orthographic projection of the first auxiliary cathode layer AC1 on the base substrate has a ring shape, e.g., a single ring or connected multiple rings. Optionally, the orthographic projection of the plurality of spacers PS on the base substrate is outside the ring shape.

Referring to FIG. 12, in some embodiments, an individual island of the plurality of islands Is includes connected multiple rings of the first auxiliary cathode layer AC1. A total number of the connected multiple rings is the same as a total number of subpixels in the individual island. For example, in FIG. 12, the individual island includes one pixel having three subpixels, the total number of the connected multiple rings is three. In some embodiments, the individual island includes one spacer of the plurality of spacers PS, and the one spacer is outside the connected multiple rings, and in one example, is located at a corner region of the individual island.

Referring to FIG. 13, in some embodiments, an individual island of the plurality of islands Is includes connected multiple rings of the first auxiliary cathode layer AC1. A total number of the connected multiple rings is the same as a total number of subpixels in the individual island. For example, in FIG. 13, the individual island includes one pixel having three subpixels, the total number of the connected multiple rings is three. In some embodiments, the individual island includes multiple spacers of the plurality of spacers PS, and the multiple spacers are outside the connected multiple rings. In one example, the individual island includes four spacers at four corner regions of the individual island, respectively.

Referring to FIG. 11, in some embodiments, an individual island of the plurality of islands Is includes a plurality of rings of the first auxiliary cathode layer AC1, the plurality of rings spaced apart from each other. In some embodiments, a respective ring of the plurality of rings of the first auxiliary cathode layer AC1 comprises connected multiple rings. In FIG. 11, the individual island of the plurality of islands Is includes nine rings arranged in an array. Each of the nine rings includes connected multiple rings. In one example, each of the nine rings includes three connected rings. In some embodiments, the individual island includes multiple spacers of the plurality of spacers PS, and the multiple spacers are outside the plurality of rings. In one example, the individual island includes four spacers. In another example, each spacer of the four spacers is between four adjacent rings of the plurality of rings.

Referring to FIG. 3 and FIG. 5, in some embodiments, an individual island of the plurality of islands Is includes a plurality of rings of the first auxiliary cathode layer AC1, the plurality of rings spaced apart from each other. In some embodiments, a respective ring of the plurality of rings of the first auxiliary cathode layer AC1 comprises connected multiple rings. In FIG. 3 and FIG. 5, the individual island of the plurality of islands Is includes four rings arranged in an array. Each of the four rings includes connected multiple rings. In one example, each of the four rings includes three connected rings. In some embodiments, the individual island includes one spacer of the plurality of spacers PS, and the one spacer is outside the plurality of rings. In one example, the one spacer is between four adjacent rings of the plurality of rings.

In some embodiments, the display panel includes a plurality of first auxiliary cathode layers in the plurality of islands, respectively. The plurality of first auxiliary cathode layers are spaced apart from each other. A respective island of the plurality of islands comprises one or more first auxiliary cathode layers of the plurality of first auxiliary cathode layers. The one or more first auxiliary cathode layers in the respective island are spaced apart from each other. Referring to FIG. 5, first auxiliary cathode layers in adjacent islands are spaced apart from each other by a first distance; the one or more first auxiliary cathode layers in the respective island are spaced apart from each other by a second distance. Optionally, the first distance is greater than the second distance.

In another aspect, the present disclosure provides a display apparatus including the display panel described herein or fabricated by a method described herein. and one or more driving circuits for driving image display in the display panel. Examples of appropriate display apparatuses include, but are not limited to, an electronic paper, a mobile phone, a tablet computer, a television, a monitor, a notebook computer, a digital album, a GPS, etc.

In another aspect, the present disclosure provides a method of fabricating a display panel. In some embodiments, the method includes forming an anode material layer comprising an anode of a light emitting element on a base substrate; forming a pixel definition layer on a side of the anode material layer away from the base substrate, and defining a subpixel aperture; forming a first auxiliary cathode layer on a side of the pixel definition layer away from the base substrate; forming an organic material layer at least partially in the subpixel aperture and on a side of the anode away from the base substrate; and forming a cathode layer on a side of the organic material layer away from the base substrate. Optionally, the first auxiliary cathode layer is connected to the cathode layer. Optionally, the first auxiliary cathode layer comprises a conductive material. Optionally, an orthographic projection of the first auxiliary cathode layer on the base substrate at least partially overlaps with an orthographic projection of the pixel definition layer on the base substrate.

In some embodiments, the method further includes forming a barrier layer on a base substrate. Various appropriate materials may be used for making the barrier layer. In one example, the barrier layer includes silicon nitride.

In some embodiments, the method further includes forming a buffer layer on a side of the barrier layer away from the base substrate. Various appropriate materials may be used for making the buffer layer. In one example, the buffer layer includes silicon oxide.

In some embodiments, the method further includes forming a semiconductor material layer on a side of the buffer layer away from the base substrate. Various appropriate materials may be used for making the semiconductor material layer. In one example, the semiconductor material layer includes silicon. In another example, the method includes depositing an amorphous silicon layer on the buffer layer, and converting at least a portion of the amorphous silicon layer into polycrystalline silicon, thereby forming an active layer of a transistor. In another example, converting the at least a portion of the amorphous silicon layer into polycrystalline silicon is performed using an excimer laser annealing process. In some embodiments, the method further includes forming a channel part of the active layer by doping, e.g., ion doping.

In some embodiments, the method further includes forming a first gate insulating layer on a side of the semiconductor material layer away from the base substrate, forming a first conductive layer including a gate electrode of the transistor on a side of the first gate insulating layer away from the base substrate, forming a second gate insulating layer on a side of the first conductive layer away from the base substrate, forming a second conductive layer on a side of the second gate insulating layer away from the base substrate, forming an insulating material layer on a side of the second conductive layer away from the base substrate, forming vias extending through the insulating material layer in a region corresponding to the plurality of islands, removing the insulating material layer, the second gate insulating layer, the first gate insulating layer, the buffer layer, the barrier layer in a region corresponding to the plurality of bridges, thereby forming the gaps.

In some embodiments, the method further includes forming a first signal line layer on a side of the inter-layer dielectric layer away from the base substrate. The first signal line layer includes a drain electrode and a source electrode in the region corresponding to the plurality of islands, and one or more first signal lines in the region corresponding to the plurality of bridges.

In some embodiments, the method further includes forming an insulating material layer on a side of the first conductive layer away from the base substrate, and forming vias extending through the insulating material layer in the region corresponding to the plurality of islands, thereby forming a first planarization layer.

In some embodiments, the method further includes forming a second signal line layer on a side of the first planarization layer away from the base substrate. The second conductive layer includes a relay electrode and a third auxiliary cathode layer in the region corresponding to the plurality of islands, and one or more second signal lines in the region corresponding to the plurality of bridges.

In some embodiments, the method further includes forming an insulating material layer on a side of the second conductive layer away from the base substrate, and forming vias extending through the insulating material layer in the region corresponding to the plurality of islands, thereby forming a second planarization layer.

In some embodiments, the method further includes forming an anode material layer on a side of the second planarization layer away from the base substrate. The anode material layer includes an anode and a second auxiliary cathode layer. In one example, the anode material layer includes a plurality of sub-layers stacked together. In one example, the anode material layer includes a stacked indium tin oxide/silver/indium tin oxide multi-layer structure.

In some embodiments, the method further includes forming an insulating material layer on a side of the anode material layer away from the base substrate, etching the insulating material layer to form a plurality of subpixel apertures extending through the insulating material layer, thereby forming a pixel definition layer.

In some embodiments, the method further includes forming a plurality of spacers on a side of the pixel definition layer away from the base substrate.

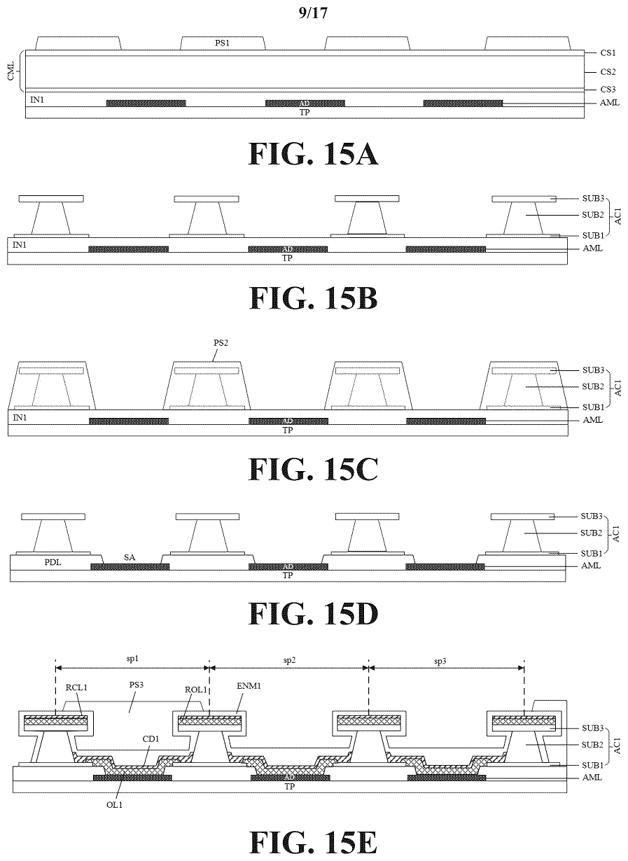

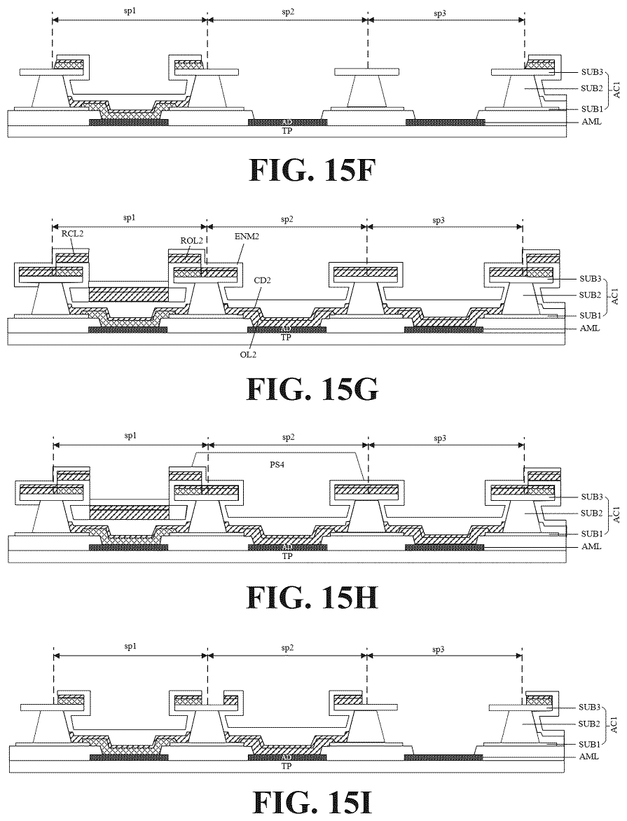

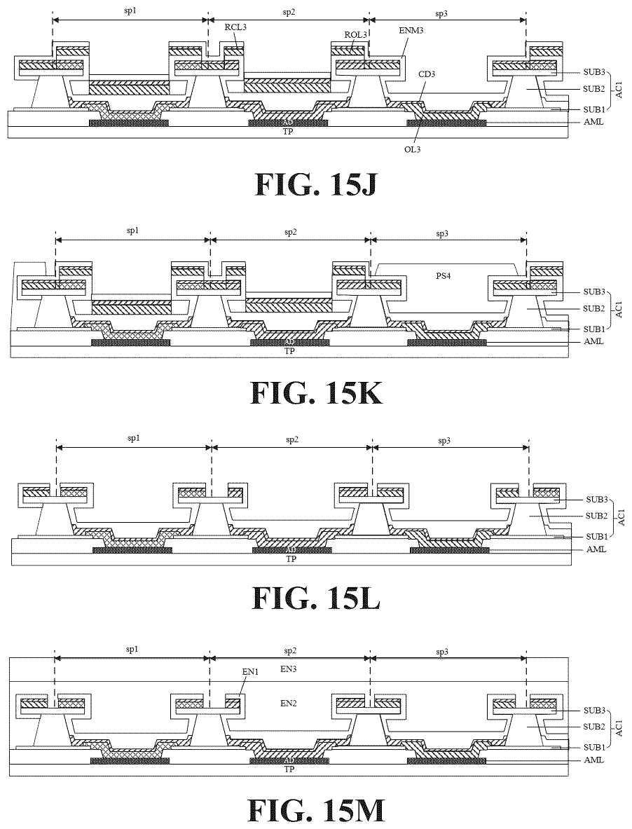

FIG. 15A to FIG. 15M illustrate a process of fabricating a display panel in some embodiments according to the present disclosure. Referring to FIG. 15A, in some embodiments, the method further includes forming a first insulating material layer IN1 on a side of the anode material layer AML away from the transistor plate TP, forming a conductive material layer CML on a side of the first insulating material layer IN1 away from the transistor plate TP, and forming a first photoresist layer PS1 on a side of the conductive material layer CML away from the transistor plate TP. The conductive material layer CML is connected to the second auxiliary cathode layer through one or more vias extending through the first insulating material layer IN1. In some embodiments, forming the conductive material layer CML includes forming a first conductive sub-layer CS1, a second conductive sub-layer CS2 on the first conductive sub-layer CS1, and a third conductive sub-layer CS3 on a side of the second conductive sub-layer CS2 away from the first conductive sub-layer CS1. In one example, the first conductive sub-layer CS1 includes titanium, the second conductive sub-layer CS2 includes aluminum, and the third conductive sub-layer CS3 includes titanium.

Referring to FIG. 15B, the method in some embodiments further includes etching the conductive material layer CML using the first photoresist layer PS1 as a mask plate, thereby forming the first auxiliary cathode layer AC1. In one example, the etching process is a wet etching process. In another example, the etching process is a dry etching process. In some embodiments, the etching process uses an etchant that selectively etches the second conductive sub-layer CS2 over the first conductive sub-layer CS1 and the third conductive sub-layer CS3. In some embodiments, the second conductive sub-layer CS2 is over-etched during the etching process. Upon completion of the etching process, the first auxiliary cathode layer AC1 is formed, including a first sub-layer SUB1, a second sub-layer SUB2 on the first sub-layer SUB1, and a third sub-layer SUB3 on a side of the second sub-layer SUB2 away from the first sub-layer SUB1.

In some embodiments, the first sub-layer SUB1 has a first width along a plane intersecting with the first auxiliary cathode layer AC1 and two adjacent anodes in two adjacent subpixels, respectively, and perpendicular to the transistor plate TP. The second sub-layer SUB2 has a second width along the plane intersecting with the first auxiliary cathode layer AC1 and two adjacent anodes in two adjacent subpixels, respectively, and perpendicular to the transistor plate TP. The third sub-layer SUB3 has a third width along a plane intersecting with the first auxiliary cathode layer AC1 and two adjacent anodes in two adjacent subpixels, respectively, and perpendicular to the transistor plate TP. In some embodiments, particularly in regions having subpixels, the first width is greater than the second width, and the third width is greater than the second width. In some embodiments, in regions where subpixels are absent (e.g., in a region outside of the plurality of islands), the first width, the second width, and the third width may have various other appropriate relationships, for example, they may be substantially the same.

Referring to FIG. 15C, the method in some embodiments further includes forming a second photoresist layer PS2 on a side of the first auxiliary cathode layer AC1 away from the first insulating material layer IN1.

Referring to FIG. 15D, the method in some embodiments further includes patterning the first insulating material layer using the second photoresist layer as a mask plate to form a pixel definition layer PDL. Specifically, patterning the first insulating material layer includes forming a plurality of subpixel apertures extending though the first insulating material layer. exposing at least a portion of the anode AD.

Referring to FIG. 15E, the method in some embodiments further includes depositing an organic material layer of a first type, the organic material layer of the first type in some embodiments is deposited using an open mask plate, thereby forming a first organic material layer OC1 in a region corresponding to a respective subpixel (e.g., a first subpixel sp1, a second subpixel sp2, and a third subpixel sp3). In one example, the organic material layer of the first type includes a light emitting material of a first color, e.g., a red light emitting material.

In some embodiments, depositing the organic material layer of the first type further forms a first residual organic material layer ROL1 stacked on the first auxiliary cathode layer AC1. The first residual organic material layer ROL1 is in a same layer as the first organic material layer OC1, and is segregated from the first organic material layer OC1 due to the pillar structure of the first auxiliary cathode layer AC1.

In some embodiments, the method further includes depositing a conductive material layer on a side of the first organic material layer away from the transistor plate TP, the conductive material layer in some embodiments is deposited using an open mask plate, thereby forming a first cathode layer CD1 in a region corresponding to a respective subpixel (e.g., a first subpixel sp1, a second subpixel sp2, and a third subpixel sp3).

In some embodiments, depositing the conductive material layer further forms a first residual cathode layer RCL1 stacked on a side of the first residual organic material layer ROL1 away from the first auxiliary cathode layer AC1. The first residual cathode layer RCL1 is in a same layer as the first cathode layer CD1, and is segregated from the first cathode layer CD1 due to the pillar structure of the first auxiliary cathode layer AC1.

In some embodiments, the method further includes forming a first encapsulating material sub-layer ENM1 on a side of the first cathode layer CD1 and the first residual cathode layer RCL1 away from the transistor plate TP.

In some embodiments, the method further includes forming a third photoresist layer PS3 in a region corresponding to the first subpixel sp1.

Referring to FIG. 15F, the method in some embodiments further includes etching the substrate using the third photoresist layer PS3 as a mask plate, thereby removing portions of the first encapsulating sub-layer, the first cathode layer, the first organic material layer, the first residual cathode layer, the first residual organic material layer in regions corresponding to the second subpixel sp2 and the third subpixel sp3.

Referring to FIG. 15G, the method in some embodiments further includes depositing an organic material layer of a second type, the organic material layer of the second type in some embodiments is deposited using an open mask plate, thereby forming a second organic material layer OC2 in a region corresponding to a respective subpixel (e.g., a first subpixel sp1, a second subpixel sp2, and a third subpixel sp3). In one example, the organic material layer of the second type includes a light emitting material of a second color, e.g., a green light emitting material.

In some embodiments, depositing the organic material layer of the second type further forms a second residual organic material layer ROL2 stacked on the first auxiliary cathode layer AC1. The second residual organic material layer ROL2 is in a same layer as the second organic material layer OC2, and is segregated from the second organic material layer OC2 due to the pillar structure of the first auxiliary cathode layer AC1.

In some embodiments, the method further includes depositing a conductive material layer on a side of the second organic material layer OC2 away from the transistor plate TP, the conductive material layer in some embodiments is deposited using an open mask plate, thereby forming a second cathode layer CD2 in a region corresponding to a respective subpixel (e.g., a first subpixel sp1, a second subpixel sp2, and a third subpixel sp3).

In some embodiments, depositing the conductive material layer further forms a second residual cathode layer RCL2 stacked on a side of the second residual organic material layer ROL2 away from the first auxiliary cathode layer AC1. The second residual cathode layer RCL2 is in a same layer as the second cathode layer CD2, and is segregated from the second cathode layer CD2 due to the pillar structure of the first auxiliary cathode layer AC1.

In some embodiments, the method further includes forming a second encapsulating material sub-layer ENM2 on a side of the second cathode layer CD2 and the second residual cathode layer RCL2 away from the transistor plate TP.

Referring to FIG. 15H, the method in some embodiments further includes forming a fourth photoresist layer PS4 in a region corresponding to the second subpixel sp2.

Referring to FIG. 151, the method in some embodiments further includes etching the substrate using the fourth photoresist layer PS4 as a mask plate, thereby removing portions of the second encapsulating material sub-layer, the second cathode layer, the second organic material layer, the second residual cathode layer, the second residual organic material layer in regions corresponding to the first subpixel sp1 and the third subpixel sp3. The first organic material layer and the first cathode layer in the first subpixel sp1 remain. The second organic material layer and the second cathode layer in the second subpixel sp2 remain.

Referring to FIG. 15J, the method in some embodiments further includes depositing an organic material layer of a third type, the organic material layer of the third type in some embodiments is deposited using an open mask plate, thereby forming a third organic material layer OC3 in a region corresponding to a respective subpixel (e.g., a first subpixel sp1, a second subpixel sp2, and a third subpixel sp3). In one example, the organic material layer of the third type includes a light emitting material of a third color, e.g., a blue light emitting material.

In some embodiments, depositing the organic material layer of the third type further forms a third residual organic material layer ROL3 stacked on the first auxiliary cathode layer AC1. The third residual organic material layer ROL3 is in a same layer as the third organic material layer OC3, and is segregated from the third organic material layer OC3 due to the pillar structure of the first auxiliary cathode layer AC1.

In some embodiments, the method further includes depositing a conductive material layer on a side of the third organic material layer OC3 away from the transistor plate TP, the conductive material layer in some embodiments is deposited using an open mask plate, thereby forming a third cathode layer CD3 in a region corresponding to a respective subpixel (e.g., a first subpixel sp1, a second subpixel sp2, and a third subpixel sp3).

In some embodiments, depositing the conductive material layer further forms a third residual cathode layer RCL3 stacked on a side of the third residual organic material layer ROL3 away from the first auxiliary cathode layer AC1. The third residual cathode Jayer RCL3 is in a same layer as the third cathode layer CD3, and is segregated from the third cathode layer CD3 due to the pillar structure of the first auxiliary cathode layer AC1.

In some embodiments, the method further includes forming a third encapsulating material sub-layer ENM3 on a side of the third cathode layer CD3 and the third residual cathode layer RCL3 away from the transistor plate TP.

Referring to FIG. 15K, the method in some embodiments further includes forming a fourth photoresist layer PS4 in a region corresponding to the third subpixel sp3.

Referring to FIG. 15L, the method in some embodiments further includes etching the substrate using the fourth photoresist layer as a mask plate, thereby removing portions of the third encapsulating material sub-layer, the third cathode layer, the third organic material layer, the third residual cathode layer, the third residual organic material layer in regions corresponding to the first subpixel sp1 and the second subpixel sp2. The first organic material layer and the first cathode layer in the first subpixel sp1 remain. The second organic material layer and the second cathode layer in the second subpixel sp2 remain. The third organic material layer and the third cathode layer in the third subpixel sp3 remain.

Referring to FIG. 15M, the method in some embodiments further includes forming a second encapsulating sub-layer EN2 on a side of the first encapsulating sub-layer EN1 away from the transistor plate, and forming a third encapsulating sub-layer EN3 on a side of the second encapsulating sub-layer EN2 away from the transistor plate.

Referring to FIG. 15A to FIG. 15M, the display panel formed by the method according to some embodiments of the present disclosure includes, on a portion of the first auxiliary cathode layer AC1 between two adjacent subpixels, two different residual organic material blocks selected from a portion of the first residual organic material layer ROL1, a portion of the second residual organic material layer ROL2, and a portion of the third residual organic material layer ROL3. Optionally, on a first portion of the first auxiliary cathode layer AC1 between a first adjacent subpixel of a first color and a second adjacent subpixel of a second color, the display panel includes a portion of the first residual organic material layer ROL1 and a portion of the second residual organic material layer ROL2. Optionally, on a second portion of the first auxiliary cathode layer AC1 between a second adjacent subpixel of a second color and a third adjacent subpixel of a third color, the display panel includes a portion of a portion of the second residual organic material layer ROL2 and a portion of the third residual organic material layer ROL3. Optionally, on a third portion of the first auxiliary cathode layer AC1 between a first adjacent subpixel of a first color and a third adjacent subpixel of a third color, the display panel includes a portion of the first residual organic material layer ROL1 and a portion of the third residual organic material layer ROL3.

In some embodiments, two different residual organic material blocks on a same portion of the first auxiliary cathode layer AC1 between two adjacent subpixels are spaced apart by a gap. In alternative embodiments, two different residual organic material blocks on a same portion of the first auxiliary cathode layer AC1 between two adjacent subpixels partially stacked on each other. In some embodiments, referring to FIG. 15M, the portion of the first residual organic material layer ROL1 and the portion of the second residual organic material layer ROL2 on the first portion of the first auxiliary cathode layer AC1 between the first adjacent subpixel of the first color and the second adjacent subpixel of the second color are spaced apart by a first gap having a first gap width. The portion of the second residual organic material layer ROL2 and the portion of the third residual organic material layer ROL3 on the second portion of the first auxiliary cathode layer AC1 between the second adjacent subpixel of the second color and the third adjacent subpixel of the third color are spaced apart by a second gap having a second gap width. The portion of the first residual organic material layer ROL1 and the portion of the third residual organic material layer ROL3 on the third portion of the first auxiliary cathode layer AC1 between the first adjacent subpixel of the first color and the third adjacent subpixel of the third color are spaced apart by a third gap having a third gap width. In one particular example as depicted in FIG. 15M, the first gap width, the second gap width, and the third gap width are different from each other. In alternative examples, at least two of the first gap width, the second gap width, and the third gap width are substantially the same.

In some embodiments, portions of the first encapsulating sub-layer EN1 encapsulating different adjacent subpixels are formed in different patterning steps. In one example, a first portion of the first encapsulating sub-layer EN1 encapsulating a first subpixel is a portion of the first encapsulating material sub-layer ENM1; a second portion of the first encapsulating sub-layer EN1 encapsulating a second subpixel is a portion of the second encapsulating material sub-layer ENM2; and a third portion of the first encapsulating sub-layer EN1 encapsulating a third subpixel is a portion of the third encapsulating material sub-layer ENM3.

In some embodiments, the organic material layer in a respective subpixel is in direct contact with the first sub-layer SUB1 of the first auxiliary cathode layer AC1, and the cathode layer in the respective subpixel is in direct contact with the first sub-layer SUB1 and the second sub-layer SUB2 of the first auxiliary cathode layer AC1.

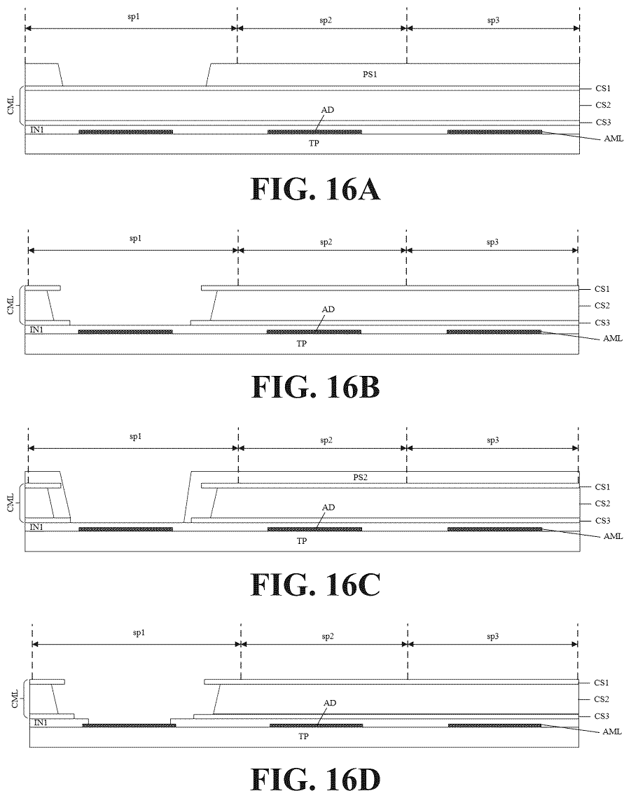

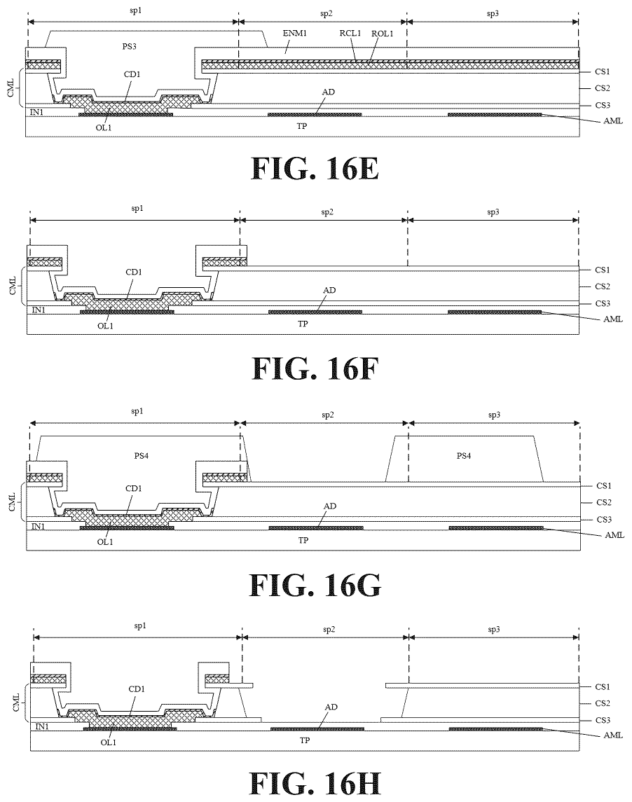

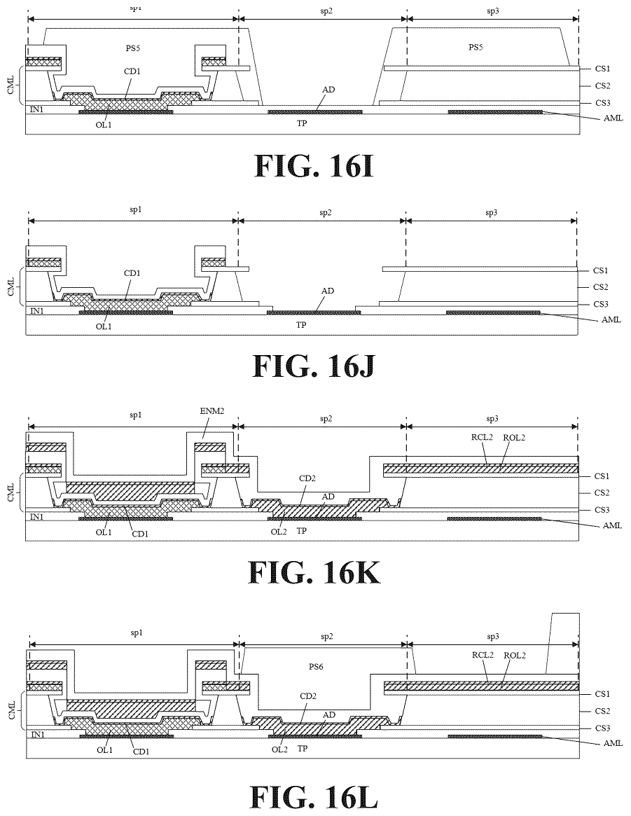

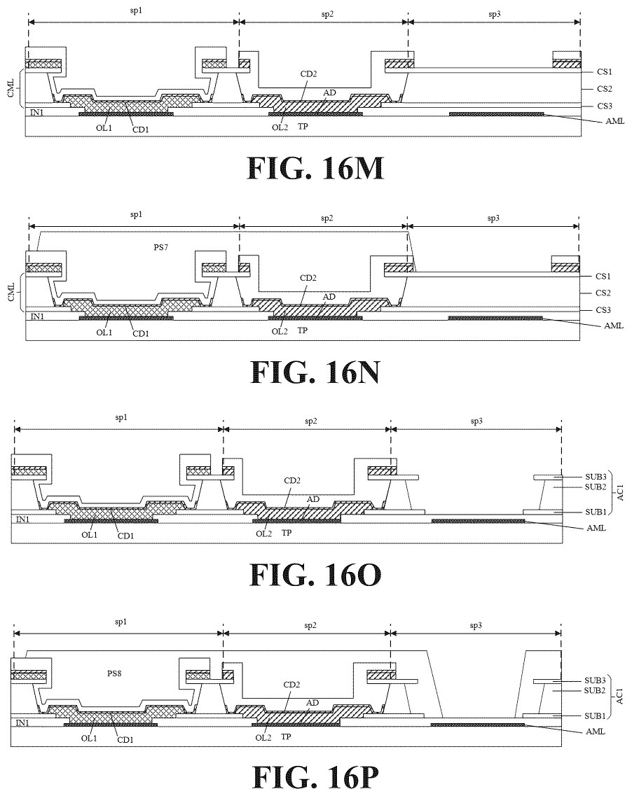

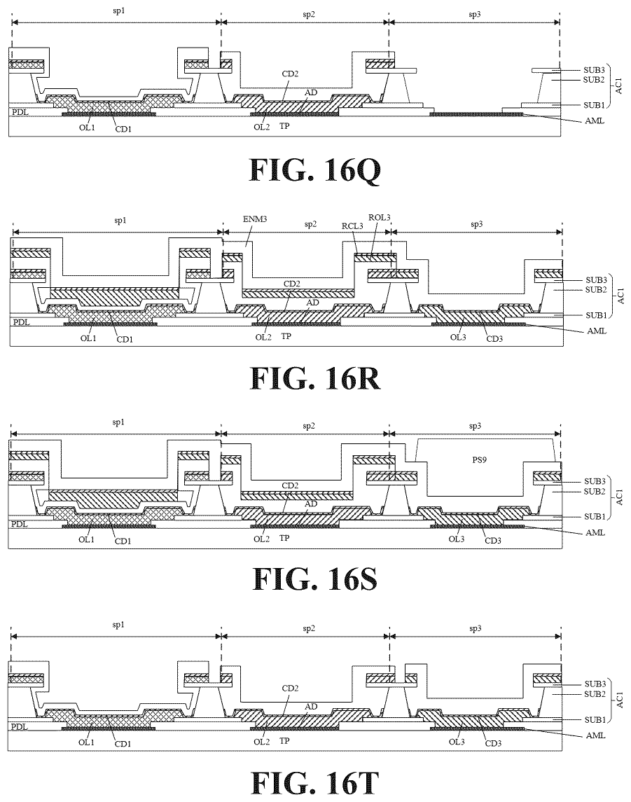

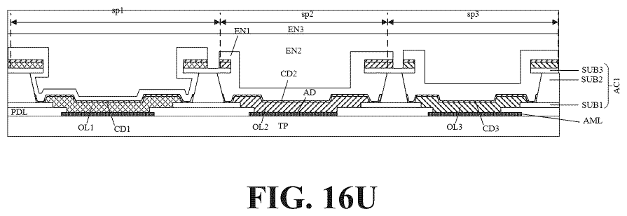

FIG. 16A to FIG. 16U illustrate a process of fabricating a display panel in some embodiments according to the present disclosure. The process depicted in FIG. 16A to FIG. 16U differs from the process depicted in FIG. 15A to FIG. 15M at least in that, subpixel apertures of subpixels are formed in multiple patterning steps with respect to subpixels of different colors in the process depicted in FIG. 16A to FIG. 16U, whereas subpixel apertures of all subpixels are formed in one single patterning step in the process depicted in FIG. 15A to FIG. 15M. Referring to FIG. 16A, in some embodiments, the method further includes forming a first insulating material layer IN1 on a side of the anode material layer AML away from the transistor plate TP, forming a conductive material layer CML on a side of the first insulating material layer IN1 away from the transistor plate TP, and forming a first photoresist layer PS1 on a side of the conductive material layer CML away from the transistor plate TP. The conductive material layer CML is connected to the second auxiliary cathode layer through one or more vias extending through the first insulating material layer IN1. In some embodiments, forming the conductive material layer CML includes forming a first conductive sub-layer CS1, a second conductive sub-layer CS2 on the first conductive sub-layer CS1, and a third conductive sub-layer CS3 on a side of the second conductive sub-layer CS2 away from the first conductive sub-layer CS1. In one example, the first conductive sub-layer CS1 includes titanium, the second conductive sub-layer CS2 includes aluminum, and the third conductive sub-layer CS3 includes titanium.

In some embodiments, the first photoresist layer PS1 covers regions corresponding to a second subpixel sp2 and a third subpixel sp3, while exposing a region corresponding to a first subpixel sp1.

Referring to FIG. 16B, the method in some embodiments further includes etching the conductive material layer CML using the first photoresist layer PS1 as a mask plate, thereby removing a portion of the conductive material layer CML in the region corresponding to a first subpixel sp1. The etching process uses an etchant that selectively etches the second conductive sub-layer CS2 over the first conductive sub-layer CS1 and the third conductive sub-layer CS3. In some embodiments, the second conductive sub-layer CS2 is over-etched during the etching process. Upon completion of the etching process, a portion of the conductive material layer CML in the region corresponding to a first subpixel sp1 is removed.

Referring to FIG. 16C, the method in some embodiments further includes forming a second photoresist layer PS2 on a side of the first auxiliary cathode layer AC1 away from the first insulating material layer IN1. In some embodiments, the second photoresist layer PS2 covers regions corresponding to a second subpixel sp2 and a third subpixel sp3, while exposing a region corresponding to a first subpixel sp1.

Referring to FIG. 16D, the method in some embodiments further includes patterning the first insulating material layer IN1 using the second photoresist layer as a mask plate, thereby removing a portion of the first insulating material layer IN1 in a region corresponding to a first subpixel sp1. Specifically, patterning the first insulating material layer includes forming a first subpixel aperture extending though the first insulating material layer, exposing at least a portion of the anode AD in the first subpixel sp1.

Referring to FIG. 16E, the method in some embodiments further includes depositing an organic material layer of a first type, the organic material layer of the first type in some embodiments is deposited using an open mask plate, thereby forming a first organic material layer OC1 in a region corresponding to the first subpixel sp1. In one example, the organic material layer of the first type includes a light emitting material of a first color, e.g., a red light emitting material.

In some embodiments, depositing the organic material layer of the first type further forms a first residual organic material layer ROL1 stacked on the conductive material layer CML, and in regions corresponding to the second subpixel sp2 and the third subpixel sp3. The first residual organic material layer ROL1 is in a same layer as the first organic material layer OC1, and is segregated from the first organic material layer OC1 due to the over-etched profile of the second conductive sub-layer CS2 along an edge of the first subpixel aperture.

In some embodiments, the method further includes depositing a conductive material layer on a side of the first organic material layer away from the transistor plate TP, the conductive material layer in some embodiments is deposited using an open mask plate, thereby forming a first cathode layer CD1 in a region corresponding to the first subpixel sp1.

In some embodiments, depositing the conductive material layer further forms a first residual cathode layer RCL1 stacked on a side of the first residual organic material layer ROL1 away from the conductive material layer CML. The first residual cathode layer RCL1 is in a same layer as the first cathode layer CD1, and is segregated from the first cathode layer CD1 due to the over-etched profile of the second conductive sub-layer CS2 along an edge of the first subpixel aperture.

In some embodiments, the method further includes forming a first encapsulating material sub-layer ENM1 on a side of the first cathode layer CD1 and the first residual cathode layer RCL1 away from the transistor plate TP.

In some embodiments, the method further includes forming a third photoresist layer PS3 in a region corresponding to the first subpixel sp1.

Referring to FIG. 16F, the method in some embodiments further includes etching the substrate using the third photoresist layer PS3 as a mask plate, thereby removing portions of the first encapsulating material sub-layer, the first residual cathode layer, the first residual organic material layer in regions corresponding to the second subpixel sp2 and the third subpixel sp3.

Referring to FIG. 16G, the method in some embodiments further includes forming a fourth photoresist layer PS4 on a side of the first cathode layer CD1 and the conductive material layer CML away from the transistor plate TP. In some embodiments, the fourth photoresist layer PS4 covers regions corresponding to the first subpixel sp1 and the third subpixel sp3, while exposing a region corresponding to the second subpixel sp2.

Referring to FIG. 16H, the method in some embodiments further includes etching the conductive material layer CML using the fourth photoresist layer PS4 as a mask plate, thereby removing a portion of the conductive material layer CML in the region corresponding to the second subpixel sp2. The etching process uses an etchant that selectively etches the second conductive sub-layer CS2 over the first conductive sub-layer CS1 and the third conductive sub-layer CS3. In some embodiments, the second conductive sub-layer CS2 is over-etched during the etching process. Upon completion of the etching process, a portion of the conductive material layer CML in the region corresponding to the second subpixel sp2 is removed.

Referring to FIG. 16I, the method in some embodiments further includes forming a fifth photoresist layer PS5 on a side of the first cathode layer CD1 and the conductive material layer CML away from the first insulating material layer IN1. In some embodiments, the fifth photoresist layer PS5 covers regions corresponding to the first subpixel sp1 and the third subpixel sp3, while exposing a region corresponding to the second subpixel sp2.

Referring to FIG. 16J, the method in some embodiments further includes patterning the first insulating material layer IN1 using the fifth photoresist layer as a mask plate, thereby removing a portion of the first insulating material layer IN1 in a region corresponding to the second subpixel sp2. Specifically, patterning the first insulating material layer includes forming a second subpixel aperture extending though the first insulating material layer, exposing at least a portion of the anode AD in the second subpixel sp2.

Referring to FIG. 16K, the method in some embodiments further includes depositing an organic material layer of a second type, the organic material layer of the second type in some embodiments is deposited using an open mask plate, thereby forming a second organic material layer OC2 in a region corresponding to the second subpixel sp2. In one example, the organic material layer of the second type includes a light emitting material of a second color, e.g., a green light emitting material.

In some embodiments, depositing the organic material layer of the second type further forms a second residual organic material layer ROL2 stacked on the conductive material layer CML, and in regions corresponding to the first subpixel sp1 and the third subpixel sp3. The second residual organic material layer ROL2 is in a same layer as the second organic material layer OC2, and is segregated from the second organic material layer OC2 due to the over-etched profile of the second conductive sub-layer CS2 along an edge of the second subpixel aperture.

In some embodiments, the method further includes depositing a conductive material layer on a side of the second organic material layer away from the transistor plate TP, the conductive material layer in some embodiments is deposited using an open mask plate, thereby forming a second cathode layer CD2 in a region corresponding to the second subpixel sp2.

In some embodiments, depositing the conductive material layer further forms a second residual cathode layer RCL2 stacked on a side of the second residual organic material layer ROL2 away from the conductive material layer CML. The second residual cathode layer RCL2 is in a same layer as the second cathode layer CD2, and is segregated from the second cathode layer CD2 due to the over-etched profile of the second conductive sub-layer CS2 along an edge of the second subpixel aperture.

In some embodiments, the method further includes forming a second encapsulating material sub-layer ENM2 on a side of the second cathode layer CD2 and the second residual cathode layer RCL2 away from the transistor plate TP.

Referring to FIG. 16L, the method in some embodiments further includes forming a sixth photoresist layer PS6 in a region corresponding to the second subpixel sp2.

Referring to FIG. 16M, the method in some embodiments further includes etching the substrate using the sixth photoresist layer as a mask plate, thereby removing portions of the second encapsulating material sub-layer, the second residual cathode layer, the second residual organic material layer in regions corresponding to the first subpixel sp1 and the third subpixel sp3.

Referring to FIG. 16N, the method in some embodiments further includes forming a seventh photoresist layer PS7 on a side of the first cathode layer CD1, the second cathode layer CD2, and the conductive material layer CML away from the transistor plate TP. In some embodiments, the seventh photoresist layer PS7 covers regions corresponding to the first subpixel sp1 and the second subpixel sp2, while exposing a region corresponding to the third subpixel sp3.

Referring to FIG. 16O, the method in some embodiments further includes etching the conductive material layer CML using the seventh photoresist layer as a mask plate, thereby removing a portion of the conductive material layer CML in the region corresponding to the third subpixel sp3. The etching process uses an etchant that selectively etches the second conductive sub-layer CS2 over the first conductive sub-layer CS1 and the third conductive sub-layer CS3. In some embodiments, the second conductive sub-layer CS2 is over-etched during the etching process. Upon completion of the etching process, a portion of the conductive material layer CML in the region corresponding to the third subpixel sp3 is removed, thereby forming the first auxiliary cathode layer AC1.

Referring to FIG. 16P, the method in some embodiments further includes forming an eighth photoresist layer PS8 on a side of the first cathode layer CD1, the second cathode layer CD2, and the first auxiliary cathode layer AC1 away from the transistor plate TP. In some embodiments, the eighth photoresist layer PS8 covers regions corresponding to the first subpixel sp1 and the second subpixel sp2, while exposing a region corresponding to the third subpixel sp3.

Referring to FIG. 16Q, the method in some embodiments further includes patterning the first insulating material layer using the eighth photoresist layer as a mask plate, thereby removing a portion of the first insulating material layer in a region corresponding to the third subpixel sp3, and forming the pixel definition layer PDL. Specifically, patterning the first insulating material layer includes forming a third subpixel aperture extending though the first insulating material layer, exposing at least a portion of the anode AD in the third subpixel sp3.

Referring to FIG. 16R, the method in some embodiments further includes depositing an organic material layer of a third type, the organic material layer of the third type in some embodiments is deposited using an open mask plate, thereby forming a third organic material layer OC3 in a region corresponding to the third subpixel sp3. In one example, the organic material layer of the third type includes a light emitting material of a third color, e.g., a blue light emitting material.

In some embodiments, depositing the organic material layer of the third type further forms a third residual organic material layer ROL3 stacked on the first auxiliary cathode layer AC1, and in regions corresponding to the first subpixel sp1 and the second subpixel sp2. The third residual organic material layer ROL3 is in a same layer as the third organic material layer OC3, and is segregated from the third organic material layer OC3 due to the over-etched profile of the second conductive sub-layer CS2 along an edge of the third subpixel aperture.

In some embodiments, the method further includes depositing a conductive material layer on a side of the third organic material layer away from the transistor plate TP, the conductive material layer in some embodiments is deposited using an open mask plate, thereby forming a third cathode layer CD3 in a region corresponding to the third subpixel sp3.

In some embodiments, depositing the conductive material layer further forms a third residual cathode layer RCL3 stacked on a side of the third residual organic material layer ROL3 away from the first auxiliary cathode layer AC1. The third residual organic material layer ROL3 is in a same layer as the third cathode layer CD3, and is segregated from the third cathode layer CD3 due to the over-etched profile of the second conductive sub-layer CS2 along an edge of the third subpixel aperture.

In some embodiments, the method further includes forming a third encapsulating material sub-layer ENM3 on a side of the third cathode layer CD3 and the third residual cathode layer RCL3 away from the transistor plate TP.

Referring to FIG. 16S, the method in some embodiments further includes forming a ninth photoresist layer PS9 in a region corresponding to the third subpixel sp3.

Referring to FIG. 16T, the method in some embodiments further includes etching the substrate using the ninth photoresist layer as a mask plate, thereby removing portions of the third encapsulating material sub-layer, the third residual cathode layer, the third residual organic material layer in regions corresponding to the first subpixel sp1 and the second subpixel sp2.

Referring to FIG. 16U, the method in some embodiments further includes forming a second encapsulating sub-layer EN2 on a side of the first encapsulating sub-layer EN1 away from the transistor plate, and forming a third encapsulating sub-layer EN3 on a side of the second encapsulating sub-layer EN2 away from the transistor plate.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A display panel, comprising:
a base substrate;
an anode material layer comprising an anode of a light emitting element on the base substrate;
a pixel definition layer on a side of the anode material layer away from the base substrate, and defining a subpixel aperture;
an organic material layer at least partially in the subpixel aperture and on a side of the anode away from the base substrate;
a cathode layer on a side of the organic material layer away from the base substrate; and
a first auxiliary cathode layer on a side of the pixel definition layer away from the base substrate;
wherein the first auxiliary cathode layer is connected to the cathode layer;
the first auxiliary cathode layer comprises a conductive material; and
an orthographic projection of the first auxiliary cathode layer on the base substrate at least partially overlaps with an orthographic projection of the pixel definition layer on the base substrate.

2. The display panel of claim 1, wherein the anode material layer further comprises a second auxiliary cathode layer;
wherein the first auxiliary cathode layer is connected to the second auxiliary cathode layer.

3. The display panel of claim 2, further comprising a third auxiliary cathode layer on a side of the anode material layer close to the base substrate;
wherein the second auxiliary cathode layer is connected to the third auxiliary cathode layer.

4. The display panel of claim 1, wherein the orthographic projection of the pixel definition layer on the base substrate substantially covers the orthographic projection of the first auxiliary cathode layer on the base substrate.

5. The display panel of claim 1, wherein the first auxiliary cathode layer is in direct contact with the pixel definition layer.

6. The display panel of claim 1, wherein the orthographic projection of the first auxiliary cathode layer on the base substrate has a ring shape; and
the orthographic projection of the first auxiliary cathode layer on the base substrate substantially surrounds at least a portion of an orthographic projection of the organic material layer on the base substrate.

7. The display panel of claim 1, wherein the orthographic projection of the first auxiliary cathode layer on the base substrate has a ring shape comprising connected multiple rings having multiple openings; and
a respective ring of the connected multiple rings substantially surrounds at least a portion of an orthographic projection of the organic material layer in a respective light emitting element of multiple light emitting elements on the base substrate.

8. The display panel of claim 1, wherein an orthographic projection of the cathode layer on the base substrate overlaps with the orthographic projection of the first auxiliary cathode layer on the base substrate, forming a first overlapping region;
the first overlapping region has a ring shape; and
the first overlapping region substantially surrounds at least a portion of an orthographic projection of the organic material layer on the base substrate.

9. The display panel of claim 8, wherein the cathode layer is in direct contact with the first auxiliary cathode layer in a region corresponding to the first overlapping region.

10. The display panel of claim 1, wherein an orthographic projection of the organic material layer on the base substrate overlaps with the orthographic projection of the first auxiliary cathode layer on the base substrate, forming a second overlapping region;
the second overlapping region has a ring shape; and
the second overlapping region substantially surrounds at least a portion of an orthographic projection of the cathode layer on the base substrate.

11. The display panel of claim 10, wherein the organic material layer is in direct contact with the first auxiliary cathode layer in a region corresponding to the second overlapping region.

12. The display panel of claim 1, wherein the first auxiliary cathode layer comprises a second sub-layer and a third sub-layer on a side of the second sub-layer away from the base substrate.

13. The display panel of claim 12, wherein the second sub-layer has a second width along a plane intersecting with the first auxiliary cathode layer and two adjacent light emitting elements in two adjacent subpixels, respectively, and perpendicular to the base substrate;
the third sub-layer has a third width along the plane intersecting with the first auxiliary cathode layer and two adjacent light emitting elements in two adjacent subpixels, respectively, and perpendicular to the base substrate; and
the third width is greater than the second width.

14. The display panel of claim 12, wherein an orthographic projection of the third sub-layer on the base substrate substantially covers an orthographic projection of the second sub-layer on the base substrate.

15. The display panel of claim 1, further comprising a residual organic material layer on a side of the first auxiliary cathode layer away from the base substrate; and
an orthographic projection of the residual organic material layer on the base substrate at least partially overlaps with the orthographic projection of the first auxiliary cathode layer on the base substrate.

16. The display panel of claim 15, further comprising a residual cathode material layer on a side of the residual organic material layer away from the first auxiliary cathode layer; and
an orthographic projection of the residual cathode material layer on the base substrate at least partially overlaps with the orthographic projection of the first auxiliary cathode layer on the base substrate.

17. The display panel of claim 1, further comprising a second signal line layer comprising a third auxiliary cathode layer;
wherein the anode material layer is on a side of the second signal line layer away from the base substrate;
the anode material layer comprising a second auxiliary cathode layer;
the cathode layer is connected to the third auxiliary cathode layer sequentially through the first auxiliary cathode layer and the second auxiliary cathode layer.

18. A display panel, comprising a plurality of islands, and a plurality of bridges connecting the plurality of islands;
wherein a respective one of the plurality of islands comprises at least one of a plurality of light emitting elements; and
the display panel comprises a plurality of first auxiliary cathode layers in the plurality of islands, respectively;
the plurality of first auxiliary cathode layers are spaced apart from each other;
a respective island of the plurality of islands comprises one or more first auxiliary cathode layers of the plurality of first auxiliary cathode layers;
the one or more first auxiliary cathode layers in the respective island are spaced apart from each other;
first auxiliary cathode layers in adjacent islands are spaced apart from each other by a first distance;
the one or more first auxiliary cathode layers in the respective island are spaced apart from each other by a second distance; and
the first distance is greater than the second distance.

19. A display apparatus, comprising the display panel of claim 1, and one or more integrated circuits connected to the display panel.

20. A method of fabricating a display panel, comprising
forming an anode material layer comprising an anode of a light emitting element on a base substrate;
forming a pixel definition layer on a side of the anode material layer away from the base substrate, and defining a subpixel aperture;
forming a first auxiliary cathode layer on a side of the pixel definition layer away from the base substrate;
forming an organic material layer at least partially in the subpixel aperture and on a side of the anode away from the base substrate;
forming a cathode layer on a side of the organic material layer away from the base substrate;
wherein the first auxiliary cathode layer is connected to the cathode layer;
the first auxiliary cathode layer comprises a conductive material;
an orthographic projection of the first auxiliary cathode layer on the base substrate at least partially overlaps with an orthographic projection of the pixel definition layer on the base substrate.
